(19) United States
(12) Patent Application Publication
(10) Pub. No.: US 2018/0292059 A1
(43) Pub. Date: Oct. 11, 2018

(54) LIGHT-EMITTING DEVICE

(71) Applicant: SHARP KABUSHIKI KAISHA, Sakai City, Osaka (JP)

(72) Inventors: MOTOI NAGAMORI, Sakai City (JP); KENJI HATAZAWA, Sakai City (JP); KOJI TAKAHASHI, Sakai City (JP); YOSHINOBU KAWAGUCHI, Sakai City (JP)

(21) Appl. No.: 15/766,910

(22) PCT Filed: Aug. 10, 2016
(86) PCT No.: PCT/JP2016/073609

§ 371 Date: Apr. 9, 2018

(30) Foreign Application Priority Data
Nov. 6, 2015 (JP) 2015-218509

(51) Int. Cl. F21S 41/16; F21V 7/04; F21V 9/30; H01S 5/022; F21S 41/173; F21V 19/00

(52) U.S. Cl. CPC F21S 41/16; F21V 7/04; F21V 9/30; F21Y 2115/10; F21S 41/173; F21V 19/001; H01S 5/022

(57) ABSTRACT

A light-emitting device includes a plurality of light source units each having a laser light source that outputs excitation light, and a phosphor unit that receives the excitation light and emits fluorescence. At least two light source units of the plurality of light source units are configured so that excitation light beams overlap each other on a light irradiation surface of the phosphor unit when the light irradiation surface is irradiated with the excitation light beams and so that longitudinal directions of long shapes of projection light beams on the light irradiation surface by the excitation light beams projected onto the light irradiation surface are parallel or substantially parallel to each other.

### TECHNICAL FIELD

The present invention relates to a light-emitting device, a lighting device, and a head lamp for a vehicle that emit fluorescence by irradiating a light irradiation surface of a phosphor unit with excitation light.

### BACKGROUND ART

Light-emitting devices that use a light emitting diode (LED) light source and a semiconductor laser (LD: Laser Diode) light source as excitation light sources and emit fluorescence by irradiating a light irradiation surface of a phosphor unit which includes a phosphor with excitation light output from the excitation light sources have been known (for example, refer to PTL 1).

Among such light-emitting devices, as compared to the light-emitting device using the light emitting diode light source, the light-emitting device using the semiconductor laser light source is able to have a smaller size (spot size) of a cross section (spot) orthogonal to an optical axis direction of an excitation light beam, and thus achieves fluorescence with high luminance. Here, in the light-emitting device using the semiconductor laser light source, since a resonance length of semiconductor laser is short and a portion of light output from a semiconductor laser element is extremely flat, a shape of the spot of the excitation light beam and accordingly a shape of a projection light beam on a light irradiation surface of a phosphor unit is normally long in shape (specifically, elliptical shapes). The projection light beam is light projected onto the light irradiation surface when the light irradiation surface is irradiated with the excitation light beam.

Meanwhile, the light-emitting device using the semiconductor laser light source may be mounted in a lighting device, such as a flood lamp, and a head lamp for a vehicle that are required to achieve fluorescence with much higher luminance, and in such a case, in order to achieve much higher luminance, the light irradiation surface of the phosphor unit is irradiated with a plurality of excitation light beams so that the excitation light beams overlap each other on the light irradiation surface, thus making it possible to further increase the luminance of the fluorescence at a part where the excitation light beams overlap each other on the light irradiation surface (for example, refer to FIG. 7 of PTL 2 and FIG. 9 of PTL 3).

### CITATION LIST

### Patent Literature

PTL 1: Japanese Unexamined Patent Application Publication No. 2011-134619

PTL 2: Japanese Patent No. 4124445

PTL 3: Japanese Unexamined Patent Application Publication No. 2015-65144

### SUMMARY OF INVENTION

### Technical Problem

However, simply irradiating the light irradiation surface of the phosphor unit with the plurality of excitation light beams so that the excitation light beams overlap each other on the light irradiation surface like a configuration in the related art described in PTL 2 or 3 leads to the following inconvenience.

FIG. 17 is a schematic plan view illustrating a configuration in the related art in which a light irradiation surface 120a of a phosphor unit 120 is irradiated with a plurality of excitation light beams L1, L2, and L3 so that the excitation light beams L1, L2, and L3 overlap each other on the light irradiation surface 120a and illustrating a state in plan view in which the excitation light beams L1, L2, and L3 overlap each other on the light irradiation surface 120a when the light irradiation surface 120a is irradiated with the excitation light beams L1, L2, and L3. Note that, FIG. 17 illustrates an example that the excitation light beams L1, L2, and L3 are output from a set of laser light sources (not illustrated) that are isotropically provided with the phosphor unit 120 therebetween, and a reference sign W indicates light irradiation directions of the set of laser light sources in FIG. 17.

In the related-art configuration, as illustrated in FIG. 17, in a case where longitudinal directions of projection light beams M1, M2, and M3 in long shapes on the light irradiation surface 120a of the phosphor unit 120 by the excitation light beams L1, L2, and L3 when the light irradiation surface 120a is irradiated with the excitation light beams L1, L2, and L3 cross each other (in particular, equally cross each other as illustrated in FIG. 17), an area of a part (refer to a hatched part of FIG. 17) where the excitation light beams L1, L2, and L3 overlap each other on the light irradiation surface 120a is reduced and light intensity of fluorescence is reduced accordingly. Thus, even when the light irradiation surface 120a of the phosphor unit 120 is irradiated with the plurality of excitation light beams L1, L2, and L3 in an overlapping manner, sufficient luminance of the fluorescence is not achieved in practice on the light irradiation surface 120a of the phosphor unit 120.

Then, the invention aims to provide a light-emitting device, a lighting device, and a head lamp for a vehicle that are able to improve luminance of fluorescence on a light irradiation surface of a phosphor unit when the light irradiation surface is irradiated with a plurality of excitation light beams in an overlapping manner.

### Solution to Problem

In order to solve the aforementioned problems, the invention provides a light-emitting device, a lighting device, and a head lamp for a vehicle as follows.

That is, a light-emitting device according to the invention is includes: a plurality of light source units each having a laser light source that outputs excitation light; and a phosphor unit that receives the excitation light and emits fluorescence; in which at least two light source units of the plurality of light source units are configured so that excitation light beams overlap each other on a light irradiation surface of the phosphor unit when the light irradiation surface is irradiated with the excitation light beams and so that longitudinal directions of projection light beams in long shapes on the light irradiation surface by the excitation light beams projected onto the light irradiation surface are parallel or substantially parallel to each other. A lighting device according to the invention includes the light-emitting device according to the invention. A head lamp for a vehicle according to the invention includes the light-emitting device according to the invention.

As an aspect of the invention, the plurality of light source units are configured so that the longitudinal directions of the shapes of all the projection light beams are parallel or substantially parallel to each other.

As an aspect of the invention, a configuration in which the longitudinal directions of the shapes of the projection light beams are horizontal directions or substantially horizontal directions when the fluorescence is projected to an outside may be provided.

As an aspect of the invention, a configuration in which the longitudinal directions of the shapes of the projection light beams of the at least two light source units are parallel or substantially parallel to a light irradiation direction along directions of the excitation light beams advancing to the light irradiation surface may be provided.

As an aspect of the invention, a configuration in which the longitudinal directions of the shapes of the projection light beams of the at least two light source units are orthogonal or substantially orthogonal to a light irradiation direction along directions of the excitation light beams advancing to the light irradiation surface may be provided.

As an aspect of the invention, a configuration in which the longitudinal directions of the shapes of the projection light beams of the at least two light source units are oblique in relation to a light irradiation direction along directions of the excitation light beams advancing to the light irradiation surface may be provided.

As an aspect of the invention, angles of the longitudinal directions of the shapes of the projection light beams relative to the light irradiation direction may be 45 degrees or substantially 45 degrees.

As an aspect of the invention, the at least two light source units may be defined as a pair of light source units each of which has the laser light source.

As an aspect of the invention, the pair of light source units may be arranged so that a light irradiation direction along the direction of the excitation light beam of one light source unit advancing to the light irradiation surface and a light irradiation direction along the direction of the excitation light beam of the other light source unit advancing to the light irradiation surface are parallel or substantially parallel.

As an aspect of the invention, the pair of light source units may be arranged so as to be positioned on one side and the other side opposite to the one side with the phosphor unit therebetween.

As an aspect of the invention, the pair of light source units may be arranged so as to face each other with the phosphor unit therebetween.

As an aspect of the invention, optical axes of the excitation light beams of the pair of light source units may be positioned on the same virtual plane or substantially same virtual plane and the same virtual plane or substantially the same virtual plane may be orthogonal or substantially orthogonal to the light irradiation surface of the phosphor unit.

As an aspect of the invention, the pair of light source units may be configured to be line-symmetric or substantially line-symmetric.

As an aspect of the invention, a plurality of pairs of light source units may be provided.

As an aspect of the invention, at least two pairs of light source units of the plurality of pairs of light source units may be configured so that the excitation light beams overlap each other on the light irradiation surface of the phosphor unit.

As an aspect of the invention, the plurality of pairs of light source units may be configured so that the light source units of each of the at least two pairs of light source units are line-symmetric or substantially line-symmetric.

As an aspect of the invention, the plurality of pairs of light source units may be arranged so that the light source units of each of the at least two pairs of light source units face each other with the phosphor unit therebetween.

As an aspect of the invention, the plurality of pairs of light source units may be configured so that, in one pair of light source units and another one pair of light source units of the plurality of pairs of light source units, a first facing direction in which the light source units as the one pair face each other and a second facing direction in which the light source units as the other one pair face each other are orthogonal or substantially orthogonal.

As an aspect of the invention, the plurality of pairs of light source units may be configured so that, in one pair of light source units and another one pair of light source units of the plurality of pairs of light source units, a first facing direction in which the light source units as the one pair face each other and a second facing direction in which the light source units as the other one pair face each other are parallel or substantially parallel.

As an aspect of the invention, optical axes of excitation light beams of the one pair of light source units and optical axes of excitation light beams of the other one pair of light source units may be positioned on the same virtual plane or substantially the same virtual plane and the same virtual plane or substantially the same virtual plane may be orthogonal or substantially orthogonal to the light irradiation surface of the phosphor unit.

As an aspect of the invention, the pair of light source units may be arranged so that a light irradiation direction along a direction of the excitation light beam of one light source unit advancing to the light irradiation surface and a light irradiation direction along a direction of the excitation light beam of the other light source unit advancing to the light irradiation surface cross each other.

As an aspect of the invention, shapes of cross sections orthogonal to optical axis directions of the excitation light beams output from the laser light sources of the at least two light source units may be defined to be all equal or substantially equal and the at least two light source units may be configured so that incidence angles of the excitation light beams radiated to the light irradiation surface of the phosphor unit are equal or substantially equal to each other.

As an aspect of the invention, the at least two light source units may be arranged so that the incidence angles of the excitation light beams radiated to the light irradiation surface increase as approaching an outer side from an inner side with the phosphor unit therebetween.

As an aspect of the invention, the at least two light source units may include reflection mirrors that reflect the excitation light beams output from the laser light sources and the phosphor unit may emit the fluorescence by receiving the excitation light beams reflected by the reflection mirrors of the at least two light source units.

As an aspect of the invention, the at least two light source units may be configured so that the excitation light beams output by the laser light sources to the reflection mirrors are parallel or substantially parallel to each other.

As an aspect of the invention, the at least two light source units may be configured so that all the excitation light beams output by the laser light sources to the reflection mirrors are orthogonal or substantially orthogonal to the light irradiation surface of the phosphor unit.

As an aspect of the invention, a configuration in which the light irradiation surface of the phosphor unit is directly irradiated with the excitation light beams from the at least two light source units may be provided.

As an aspect of the invention, a reflective light emitting principle in which the excitation light beams are radiated to the light irradiation surface of the phosphor unit to output the fluorescence from the light irradiation surface may be used.

As an aspect of the invention, a transmissive light emitting principle in which the excitation light beams are radiated to the light irradiation surface of the phosphor unit to output the fluorescence from a surface opposite to the light irradiation surface may be used.

As an aspect of the invention, a projecting lens that projects the fluorescence from a surface from which the fluorescence is output among the light irradiation surface and the surface opposite to the light irradiation surface in the phosphor unit may be included.

As an aspect of the invention, the incidence angles of the excitation light beams to the light irradiation surface of the phosphor unit may be larger than a take-in angle of the projecting lens.

As an aspect of the invention, a reflector that projects the fluorescence from the light irradiation surface of the phosphor unit may be provided.

### Advantageous Effects of Invention

According to the invention, it is possible to improve luminance of fluorescence on a light irradiation surface of a phosphor unit when the light irradiation surface is irradiated with a plurality of excitation light beams in an overlapping manner.

### BRIEF DESCRIPTION OF DRAWINGS

FIG. 1 is a sectional view illustrating a schematic configuration of a light-emitting device according to a first embodiment.

FIG. 2 is a schematic view illustrating light source units, a phosphor unit, and a projecting lens of the light-emitting device illustrated in FIG. 1, in which FIGS. 2(a) and 2(b) are respectively a side view thereof and a plan view thereof.

FIG. 3 is an explanatory view for explaining a state of a projection light beam on a light irradiation surface of a phosphor unit in a case where an excitation light beam is radiated to the light irradiation surface at an incidence angle, in which FIG. 3(a) is a schematic sectional view illustrating the excitation light beam with the incidence angle and the projection light beam on the light irradiation surface to which the excitation light beam is radiated, and FIGS. 3(b) to 3(d) are schematic plan views of a cross section of the excitation light beam orthogonal to an optical axis direction and a shape of a projection light beam in plan view, in a case where a longitudinal direction of the shape of the projection light beam is parallel or substantially parallel to a light irradiation direction along a direction of the excitation light beam advancing to the light irradiation surface, a case where the longitudinal direction is orthogonal or substantially orthogonal to the light irradiation direction, and a case where the longitudinal direction is oblique in relation to the light irradiation direction, respectively.

FIG. 4 is a schematic plan view illustrating projection light beams on the light irradiation surface by excitation light beams projected onto the light irradiation surface in the light-emitting device according to the first embodiment, in which FIGS. 4(a) to 4(c) illustrate a state of the projection light beams in a case where longitudinal directions of shapes of the projection light beams are parallel or substantially parallel to the light irradiation direction, a case where the longitudinal directions are orthogonal or substantially orthogonal to the light irradiation direction, and a case where the longitudinal directions are oblique in relation to the light irradiation direction, respectively.

FIG. 5 is a schematic view illustrating an example of a light-emitting device according to a second embodiment, in which FIGS. 5(a) and 5(b) are respectively a side view and a plan view illustrating an example that the light-emitting device according to the first embodiment further includes a pair of light source units.

FIG. 6 is a schematic plan view illustrating projection light beams on the light irradiation surface by excitation light beams projected onto the light irradiation surface in the light-emitting device according to the second embodiment illustrated in FIG. 5, in which FIGS. 6(a) to 6(e) illustrate each example thereof.

FIG. 7 is a schematic plan view illustrating the projection light beams on the light irradiation surface by the excitation light beams projected onto the light irradiation surface in the light-emitting device according to the second embodiment illustrated in FIG. 5, in which FIGS. 7(a) to 7(d) illustrate each example thereof.

FIG. 8 is a schematic sectional view illustrating a case where a main body chassis is fixed to a table in the example illustrated in FIG. 6(a).

FIG. 9 is a schematic sectional view illustrating a case where the main body chassis is fixed to the table in the example illustrated in FIG. 6(c).

FIG. 10 is a schematic view illustrating another example of the light-emitting device according to the second embodiment, in which FIGS. 10(a) and 10(b) are respectively a side view and a plan view illustrating another example that the light-emitting device according to the first embodiment further includes a pair of light source units.

FIG. 11 is a schematic plan view illustrating the projection light beams on the light irradiation surface by the excitation light beams projected onto the light irradiation surface in the light-emitting device according to the second embodiment illustrated in FIG. 10, in which FIGS. 11(a) to 11(e) illustrate each example thereof.

FIG. 12 is a schematic plan view illustrating the projection light beams on the light irradiation surface by the excitation light beams projected onto the light irradiation surface in the light-emitting device according to the second embodiment illustrated in FIG. 10, in which FIGS. 12(a) to 12(d) illustrate each example thereof.

FIG. 13 is a schematic view illustrating a light-emitting device according to a third embodiment and is a sectional view illustrating an example that the light irradiation surface of the phosphor unit is directly irradiated with the excitation light beams from the light source units.

FIG. 14 is a schematic view illustrating a light-emitting device according to a fourth embodiment and is a sectional view illustrating an example of a transmissive configuration.

FIG. 15 is a schematic view illustrating a light-emitting device according to a fifth embodiment and is a side view illustrating an example that light irradiation directions of a pair of light source units cross each other.

FIG. 16 is a schematic view illustrating a light-emitting device according to a sixth embodiment and is a side view illustrating an example that a reflector is provided.

FIG. 17 is a schematic plan view illustrating a configuration in the related art in which a light irradiation surface of a phosphor unit is irradiated with a plurality of excitation light beams so that the excitation light beams overlap on the light irradiation surface, and illustrating a state in plan view in which the excitation light beams overlap each other on the light irradiation surface when the light irradiation surface is irradiated with the excitation light beams.

### DESCRIPTION OF EMBODIMENTS

Hereinafter, embodiments according to the invention will be described with reference to drawings.

### First Embodiment

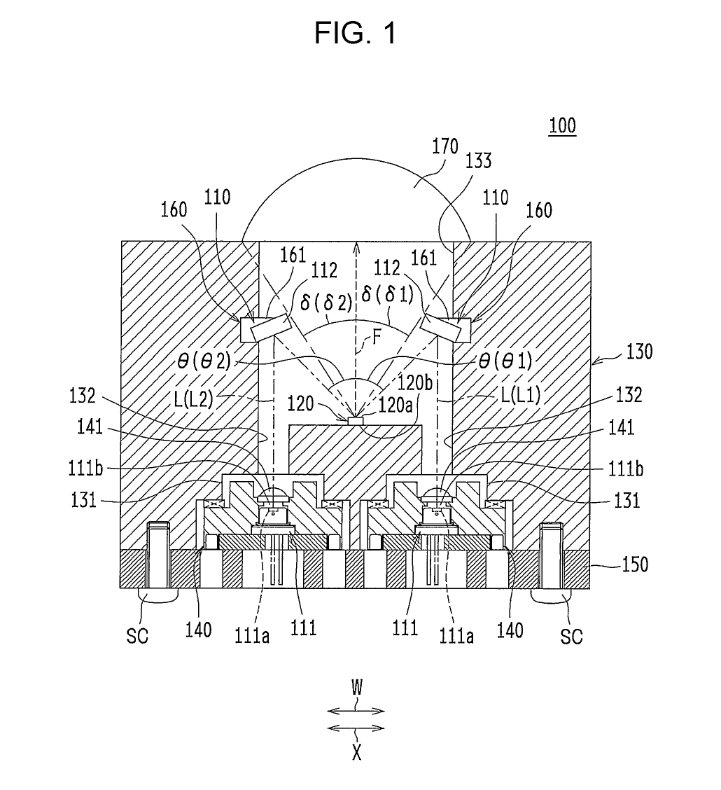

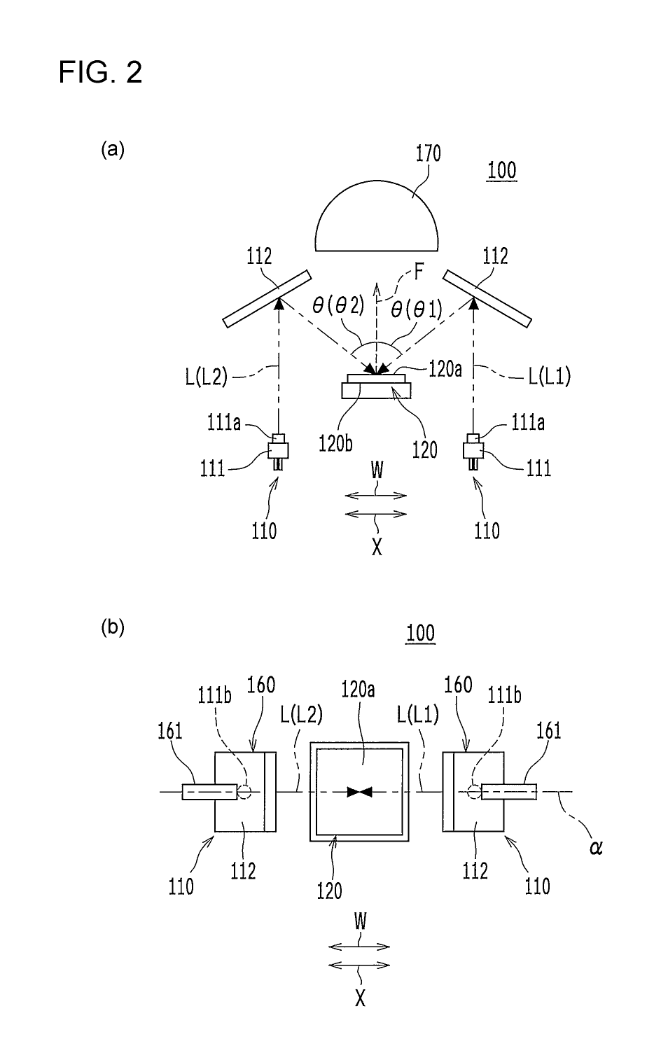

FIG. 1 is a sectional view illustrating a schematic configuration of a light-emitting device 100 according to a first embodiment. FIG. 2 is a schematic view illustrating light source units 110 to 110, a phosphor unit 120, and a projecting lens 170 of the light-emitting device 100 illustrated in FIG. 1, in which FIGS. 2(a) and 2(b) are respectively a side view thereof and a plan view thereof.

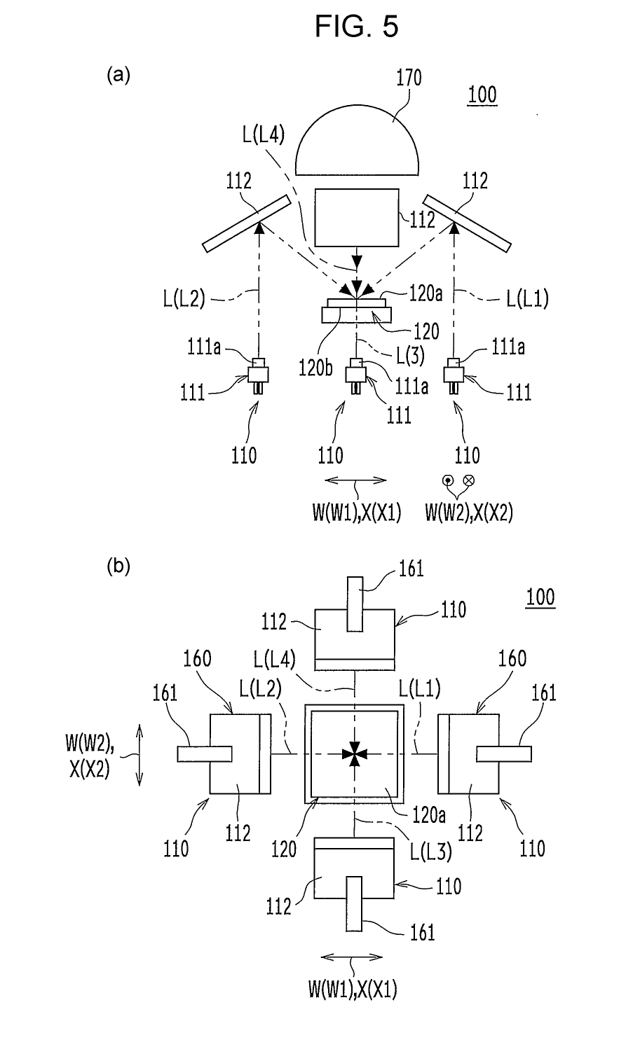

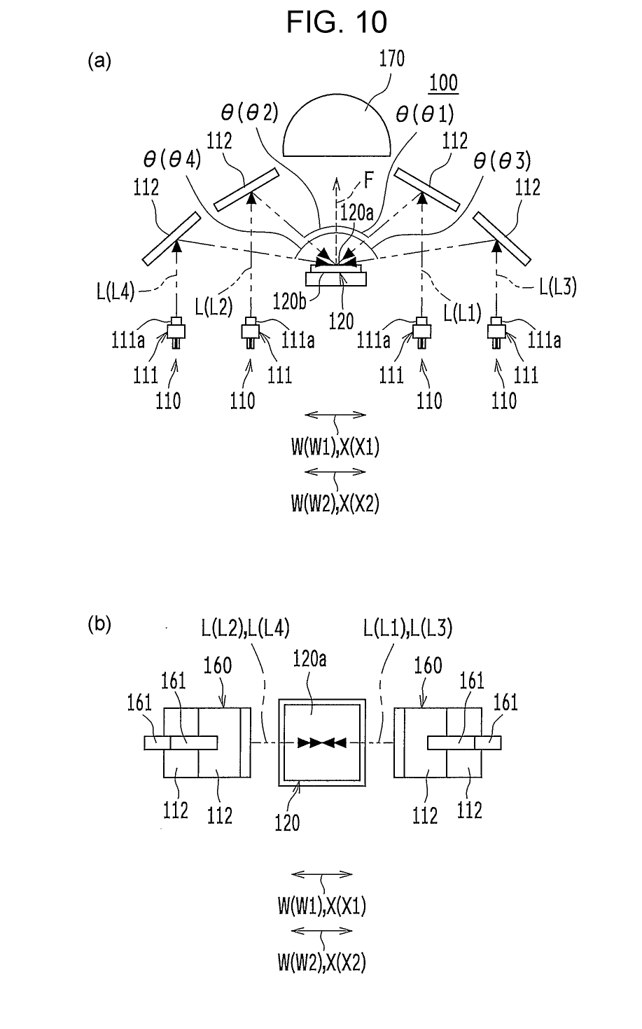

Note that, in FIG. 2(b), while illustration of the projecting lens 170 is omitted, a holding member 161 is illustrated. The same is applied also to FIGS. 5(b) and 10(b) described later.

As illustrated in FIGS. 1 and 2, the light-emitting device 100 includes a plurality of (in the present example, two) light source units 110 to 110, each of which has a laser light source 111 [refer to FIGS. 1 and 2(a)] that outputs an excitation light beam L, and the phosphor unit 120 that emits fluorescence F [refer to FIGS. 1 and 2(a)] by receiving a plurality of (in the present example, two) excitation light beams L to L.

Any color is able to be selected as a color of the fluorescence F (more accurately, a projection light beam M resulting from a color mixture of the excitation light beam L and the fluorescence F) in accordance with intended use.

For example, white light that is obtained by irradiating a phosphor that emits yellow light by using blue laser as the excitation light beam L is suitable for a head lamp for a motor vehicle. White light obtained by irradiating a phosphor that emits red light and green light by using blue laser as the excitation light beam L is also suitable. Specifically, a plurality of (in the present example, two) laser light sources 111 to 111 are defined as laser light sources each of which includes a semiconductor laser element 111a (LD: Laser Diode) [refer to FIGS. 1 and 2(a)].

The phosphor unit 120 includes a phosphor. Note that, each of a plurality of (in the present example, two) semiconductor laser elements 111a to 111a and the phosphor unit 120 may be a known element or unit and detailed description thereof is omitted here.

The light-emitting device 100 uses, as illumination light, the fluorescence F [refer to FIGS. 1 and 2(a)] that is generated by irradiating a light irradiation surface 120a of the phosphor unit 120 with the excitation light beams L to L that are respectively output from the laser light sources 111 to 111. Here, not only shapes of cross sections (spots) of the excitation light beams L to L orthogonal to axial directions but also shapes of projection light beams M to M on the light irradiation surface 120a of the phosphor unit 120 by the excitation light beams L to L projected onto the light irradiation surface 120a when the light irradiation surface 120a is irradiated with the excitation light beams L to L have a long shape (specifically, elliptical shape). A ratio of a longitudinal size and a transverse size of the shapes of the spots of the excitation light beams L to L is not limited but may be, for example, about 10:3.

Specifically, the light-emitting device 100 further includes a main body chassis 130 (refer to FIG. 1), a plurality of (in the present example, two) light source units 140 to 140 (refer to FIG. 1), and a pressing plate 150 (refer to FIG. 1).

The main body chassis 130 constitutes a main body portion of the light-emitting device 100. The main body chassis 130 is provided with housing units 131 (refer to FIG. 1) in which the light source units 140 to 140 are respectively housed.

The light source units 140 to 140 include the laser light sources 111 to 111 that respectively constitute the light source units 110 to 110, and are housed in a plurality of (in the present example, two) housing units 131 to 131 of the main body chassis 130 while holding the laser light sources 111 to 111 and fixed to the main body chassis 130 with fixing members SC to SC (refer to FIG. 1), such as screws, on the pressing plate 150.

The main body chassis 130 is provided with excitation-light-passing holes 132 to 132 for passing the excitation light beams L to L output from the light source units 140 to 140, respectively. The main body chassis 130 is also provided with a projection-light-passing hole 133 for passing the projection light beams M to M output from the light irradiation surface 120a of the phosphor unit 120.

The excitation-light-passing holes 132 to 132 are provided along optical axis directions or substantially optical axis directions of the excitation light beams L to L output from the light source units 140 to 140. The projection-light-passing hole 133 is provided along a direction orthogonal or substantially orthogonal to the light irradiation surface 120a. In the present example, the excitation-light-passing holes 132 to 132 and the projection-light-passing hole 133 are provided to communicate with each other in the main body chassis 130.

Further, the light source units 110 to 110 include reflection mirrors 112 that reflect the excitation light beams L to L output from the laser light sources 111 to 111.

The light-emitting device 100 further includes a plurality of (in the present example, two) mirror units 160 to 160 (refer to FIG. 1). The mirror units 160 to 160 include the reflection mirrors 112 to 112 that respectively constitute the light source units 110 to 110, and a plurality of (in the present example, two) holding members 161 to 161 [refer to FIGS. 1 and 2(b)] that respectively hold the plurality of (in the present example, two) reflection mirrors 112 to 112 with respect to the main body chassis 130. Specifically, the reflection mirrors 112 to 112 are provided on an inner wall of the projection-light-passing hole 133 of the main body chassis 130 through the holding members 161 to 161, respectively.

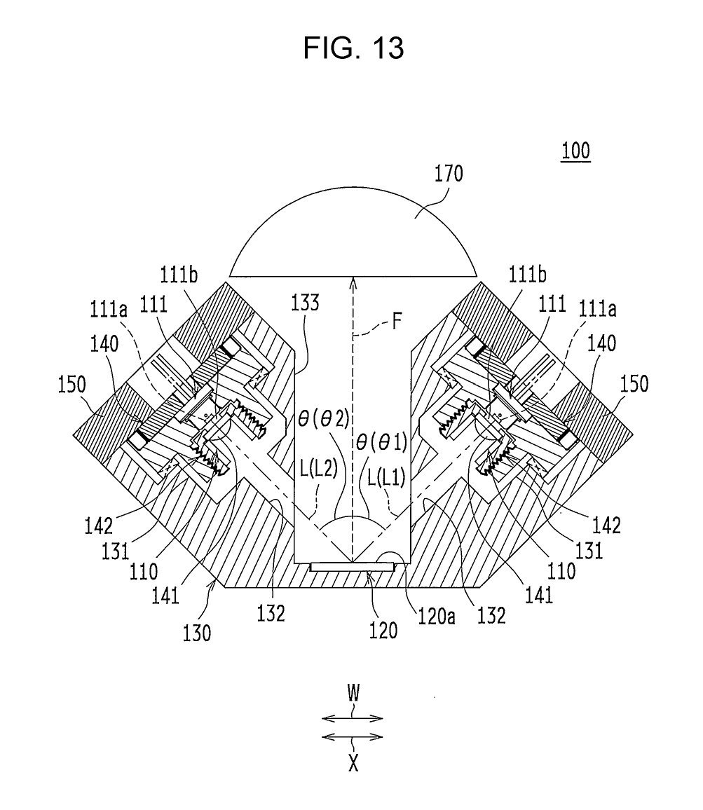

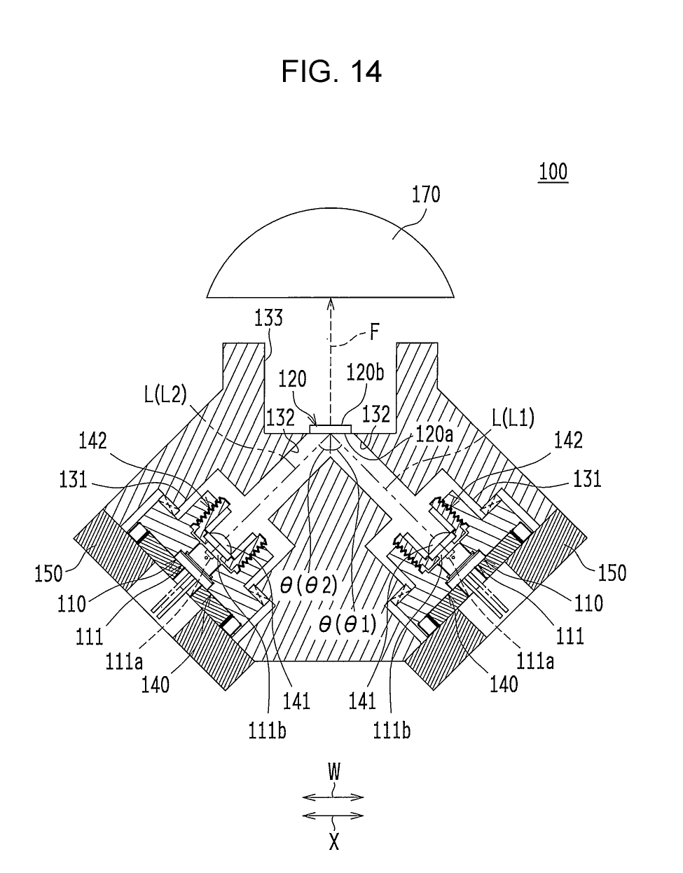

The light source units 140 to 140 further include collimate lenses 141 to 141 (refer to FIG. 1), respectively. The plurality of (in the present example, two) collimate lenses 141 to 141 are respectively provided near light output openings 111b to 111b [refer to FIGS. 1 and 2(b)] of the laser light sources 111 to 111. The collimate lenses 141 to 141 are optical members that adjust (for example, reduce) sizes (spot sizes) or the like of the cross sections (spots) of the excitation light beams L to L orthogonal to the optical axis directions after the excitation light beams L to L are appropriately radiated to the reflection mirrors 112 to 112. The collimate lenses 141 to 141 are able to be constituted by optical members, for example, such as convex lenses. The light source units 140 to 140 are able to adjust the spot sizes of the excitation light beams L to L by moving the collimate lenses 141 to 141 in optical axis directions to thereby perform the movement in the optical axis directions while rotating the collimate lenses 141 to 141 about axes along the optical axes with screw structures 142 to 142 (not illustrated in FIG. 1, refer to FIGS. 13 and 14 described later).

The light-emitting device 100 further includes the projecting lens 170 [refer to FIGS. 1 and 2(a)] that projects the fluorescence F from a surface (in the present example, the light irradiation surface 120a) from which the fluorescence F is output among the light irradiation surface 120a and a surface 120b [refer to FIGS. 1 and 2(a)] opposite to the light irradiation surface 120a in the phosphor unit 120.

In the present example, the laser light sources 111 to 111 are provided on the opposite side of the light irradiation surface 120a of the phosphor unit 120 and the reflection mirrors 112 to 112 are provided at positions between the phosphor unit 120 and the projecting lens 170.

In the light-emitting device 100 described above, the excitation light beams L to L output from the laser light sources 111 to 111 are reflected by the reflection mirrors 112 to 112 and radiated to the light irradiation surface 120a of the phosphor unit 120, so that the fluorescence F is generated. Then, the fluorescence F output from the surface (in the present example, the light irradiation surface 120a) on the side in which the fluorescence F is output is projected to the outside through the projecting lens 170.

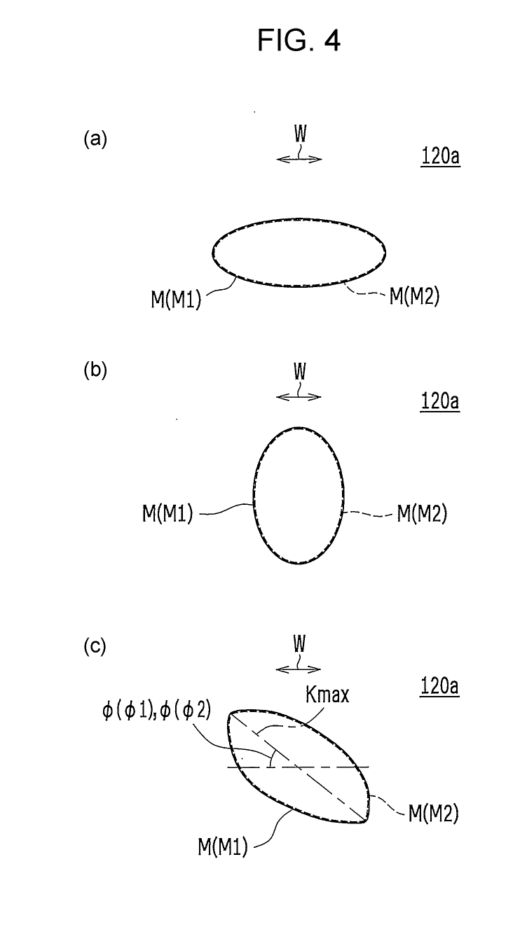

In the first embodiment, the plurality of light source units 110 to 110 are configured (specifically arranged, or more specifically arranged being adjusted) so that the excitation light beams L to L overlap each other on the light irradiation surface 120a of the phosphor unit 120 (preferably, so that at least one of the excitation light beams entirely overlaps the other excitation light beams on the light irradiation surface 120a) when the light irradiation surface 120a is irradiated with the excitation light beams L to L, and so that longitudinal directions of the projection light beams M to M in a long shape (refer to FIG. 4 described later) on the light irradiation surface 120a by the excitation light beams L to L projected onto the light irradiation surface 120a are parallel or substantially parallel to each other.

In the present example, the plurality of light source units 110 to 110 are configured so that the longitudinal directions of the shapes of all the projection light beams M to M are parallel or substantially parallel.

The plurality of light source units 110 to 110 are configured so that the longitudinal directions of the shapes of the projection light beams M to M are horizontal directions or substantially horizontal directions when the fluorescence F is projected to the outside.

As an aspect in which the plurality of light source units 110 to 110 are adjusted so that the excitation light beams L to L overlap each other on the light irradiation surface 120a and the longitudinal directions of the projection light beams M to M in a long shape are parallel or substantially parallel to each other, for example, an aspect in which the adjustment is performed by moving the laser light sources 111 to 111 (in the present example, the light source units 140 to 140) in a direction along a surface orthogonal to the optical axis directions of the excitation light beams L and in a rotation direction about axes along the optical axis directions of the excitation light beams L is able to be exemplified. Note that, such adjustment is able to be performed, for example, when an operator moves the light source units 140 to 140 with use of an adjustment jig while observing a monitor of a magnified display device.

According to the present embodiment, the plurality of light source units 110 to 110 are configured so that the excitation light beams L to L overlap each other on the light irradiation surface 120a of the phosphor unit 120 when the light irradiation surface 120a is irradiated with the excitation light beams L to L and the longitudinal directions of the projection light beams M to M in the long shape on the light irradiation surface 120a by the excitation light beams L to L projected onto the light irradiation surface 120a are parallel or substantially parallel to each other, thus making it possible to increase an area of a part where the excitation light beams L to L overlap each other on the light irradiation surface 120a of the phosphor unit 120 to 120, and it is possible to improve light intensity of the fluorescence F accordingly. As a result, it is possible to improve the luminance of the fluorescence F on the light irradiation surface 120a of the phosphor unit 120 when the light irradiation surface 120a of the phosphor unit 120 is irradiated with the plurality of excitation light beams L to L in an overlapping manner.

When the plurality of light source units 110 to 110 are configured so that the longitudinal directions of the shapes of all the projection light beams M to M are parallel or substantially parallel, the light intensity of the fluorescence F is able to be improved effectively. Thus, it is possible to further enhance the luminance of the fluorescence F on the light irradiation surface 120a of the phosphor unit 120 when the light irradiation surface 120a of the phosphor unit 120 is irradiated with the plurality of excitation light beams L to L in an overlapping manner.

The plurality of light source units 110 to 110 are configured so that the longitudinal directions of the shapes of the projection light beams M to M are horizontal directions or substantially horizontal directions when the fluorescence F is projected to the outside, thus allowing suitable usage in an application, such as a head lamp for a motor vehicle, in which directivity characteristics that are wide in a horizontal direction are desired.

Note that, reference signs that are not described in FIG. 1 or 2 will be described later.

### About First Embodiment-1 to 4

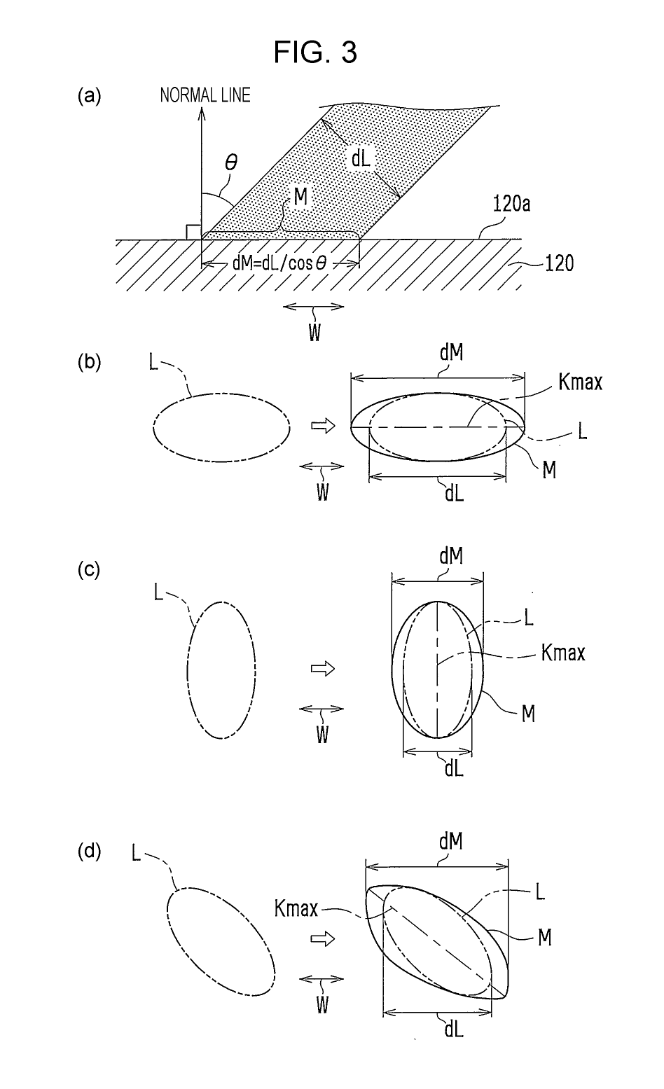

FIG. 3 is an explanatory view for explaining a state of a projection light beam M on the light irradiation surface 120a of the phosphor unit 120 in a case where the excitation light beam L is radiated to the light irradiation surface 120a of the phosphor unit 120 at an incidence angle θ. FIG. 3(a) is a schematic sectional view illustrating the excitation light beam L with the incidence angle θ and the projection light beam M on the light irradiation surface 120a to which the excitation light beam L is radiated, and FIGS. 3(b) to 3(d) are schematic plan views of a cross section of the excitation light beam L orthogonal to an optical axis direction and a shape of the projection light beam M in plan view, in a case where the longitudinal direction of the shape of the projection light beam M is parallel or substantially parallel to a light irradiation direction W along a direction of the excitation light beam L advancing to the light irradiation surface 120a, a case where the longitudinal direction is orthogonal or substantially orthogonal to the light irradiation direction W, and a case where the longitudinal direction is oblique in relation to the light irradiation direction W, respectively. Note that, in FIG. 3, the light source units 110 to 110 are set as a pair of light source units 110 and 110, and one excitation light beam L and one projection light beam M among a pair of excitation light beams L and L and a pair of projection light beams M and M are indicated as representatives instead of the other excitation light beam L and the other projection light beam M, and the other excitation light beam L and the other projection light beam M are not illustrated.

Here, the longitudinal direction of the projection light beam M is able to be exemplified as a direction of a straight line Kmax [refer to FIGS. 3(b) to 3(d)] which is the longest among straight lines drawn from one end to the other end of the projection light beam M in the long shape. A transverse direction of the projection light beam M is able to be exemplified as a direction of a straight line which is the shortest among the straight lines drawn from one end to the other end of the projection light beam M in the long shape.

As illustrated in FIG. 3, when the excitation light beams L and L have the incidence angles θ and θ [refer to FIGS. 1, 2(a), and 3(a)] relative to the light irradiation surface 120a of the phosphor unit 120, a size dM (=dL/cos θ) [refer to FIG. 3(a)] of the shape of each of the projection light beams M and M in the light irradiation direction W is larger than a size dL (spot size), in the light irradiation direction W, of the shape of the cross section (spot) of the excitation light beam L orthogonal to the optical axis direction by (dL/cos θ)−dL.

That is, as orientations (angles) of the longitudinal directions of the shapes of the projection light beams M and M with respect to the light irradiation direction W vary, longitudinal sizes or transverse sizes of the shapes of the projection light beams M and M become different. Thus, it is desired that the orientations of the longitudinal directions of the shapes of the projection light beams M and M with respect to the light irradiation direction W are decided depending on intended use of the light-emitting device 100. Here, the light irradiation direction W may be said as a direction along an incidence direction and a reflection direction of the excitation light beam L with respect to the light irradiation surface 120a.

This will be described below with reference to FIG. 4 while the light source units 110 to 110 are defined as a pair of light source units 110 and 110.

FIG. 4 is a schematic plan view illustrating the projection light beams M to M on the light irradiation surface 120a by the excitation light beams L to L projected onto the light irradiation surface 120a in the light-emitting device 100 according to the first embodiment. FIGS. 4(a) to 4(c) illustrate a state of the projection light beams M to M in a case where the longitudinal directions of the shapes of the projection light beams M to M are parallel or substantially parallel to the light irradiation direction W, a case where the longitudinal directions are orthogonal or substantially orthogonal to the light irradiation direction W, and a case where the longitudinal directions are oblique in relation to the light irradiation direction W, respectively.

### First Embodiment-1

In this respect, in the present example, in the light-emitting device 100 according to the first embodiment, the pair of light source units 110 and 110 is configured (specifically arranged, or more specifically arranged being adjusted) so that the longitudinal directions of the shapes of the projection light beams M(M1) and M(M2) of the pair of light source units 110 and 110 are parallel or substantially parallel to the light irradiation direction W along directions of the excitation light beams L(L1) and L(L2) advancing to the light irradiation surface 120a [refer to FIG. 4(a)].

According to such a configuration, when the light source units 110 and 110 are configured so that the longitudinal directions of the shapes of the projection light beams M(M1) and M(M2) of the light source units 110 and 110 are parallel or substantially parallel to the light irradiation direction W, as the incidence angles θ(θ1) and θ(θ2) of the excitation light beams L(L1) and L(L2) to the light irradiation surface 120a of the phosphor unit 120 increase, the longitudinal sizes of the shapes of the projection light beams M(M1) and M(M2) are large, thus allowing suitable usage in an application (for example, a head lamp for a vehicle which is desired to have directivity characteristics that are wide in a horizontal direction) in which directivity characteristics that are wide in a given straight line direction are desired.

### First Embodiment-2

In the present example, in the light-emitting device 100 according to the first embodiment, the pair of light source units 110 and 110 is configured (specifically arranged, or more specifically arranged being adjusted) so that the longitudinal directions of the shapes of the projection light beams M(M1) and M(M2) of the pair of light source units 110 and 110 are orthogonal or substantially orthogonal to the light irradiation direction W along the directions of the excitation light beams L(L1) and L(L2) advancing to the light irradiation surface 120a [refer to FIG. 4 (b)].

According to such a configuration, when the light source units 110 and 110 are configured so that the longitudinal directions of the shapes of the projection light beams M(M1) and M(M2) of the light source units 110 and 110 are orthogonal or substantially orthogonal to the light irradiation direction W, as the incidence angles θ(θ1) and θ(θ2) of the excitation light beams L(L1) and M(L2) to the light irradiation surface 120a of the phosphor unit 120 increase, the transverse sizes of the shapes of the projection light beams M(M1) and M(M2) are large and the shapes of the projection light beams M(M1) and M(M2) approach a perfect circle, thus allowing suitable usage in an application (for example, a flood lamp which is desired to have directivity characteristics that are wide in substantially all directions) in which directivity characteristics that are wide in substantially all directions are desired.

### First Embodiment-3

Meanwhile, in a case where the light-emitting device 100 is provided in a horizontal direction or a vertical direction, in the present example, when the pair of light source units 110 and 110 is arranged so that the light irradiation direction W is oblique (in a diagonal direction) in relation to the horizontal direction, directivity characteristics that are wide in the horizontal direction or the vertical direction are desired in some cases. Thus, in a case where the light source units 110 and 110 are arranged so that the light irradiation direction W is oblique in relation to the horizontal direction or the vertical direction, it is desired to cope with directivity characteristics that are wide in the horizontal direction or the vertical direction.

In this respect, in the light-emitting device 100 according to the first embodiment, in the present example, the pair of light source units 110 and 110 is configured (specifically arranged, or more specifically arranged being adjusted) so that the longitudinal directions (or the transverse directions) of the shapes of the projection light beams M(M1) and M(M2) of the pair of light source units 110 and 110 are oblique in relation to the light irradiation direction W along the directions of the excitation light beams L(L1) and L(L2) advancing to the light irradiation surface 120a [refer to FIG. 4(c)].

According to such a configuration, in a case where the light source units 110 and 110 are configured so that the longitudinal directions (or the transverse directions) of the shapes of the projection light beams M(M1) and M(M2) of the light source units 110 and 110 are oblique in relation to the light irradiation direction W, suitable usage is enabled in an application (for example, a head lamp for a vehicle which is desired to have directivity characteristics that are wide in the horizontal direction) in which directivity characteristics that are wide in the horizontal direction or the vertical direction are desired, when the light source units 110 and 110 are arranged so that the light irradiation direction W is oblique in relation to the horizontal direction or the vertical direction, resulting that it is possible to cope with directivity characteristics that are wide in the horizontal direction or the vertical direction.

### First Embodiment-4

In the light-emitting device 100 according to the first embodiment, angles φ(φ1) and φ(φ2) [refer to FIG. 4(c)] of the longitudinal directions (or the transverse directions) of the shapes of the projection light beams M(M1) and M(M2) relative to the light irradiation direction W are 45 degrees or substantially 45 degrees.

According to such a configuration, when the angles φ(φ1) and φ(φ2) of the longitudinal directions (or the transverse directions) of the shapes of the projection light beams M(M1) and M(M2) relative to the light irradiation direction W are 45 degrees or substantially 45 degrees, in the present example, the pair of light source units 110 and 110 is able to be provided at an intermediate position between the horizontal direction and the vertical direction, and it is possible to realize reduction in a size of the light-emitting device 100 accordingly.

### First Embodiment-5

In the light-emitting device 100 according to the first embodiment, the light source units 110 to 110 are defined as the pair of light source units 110 and 110 each having the laser light source 111 as described above.

According to such a configuration, when the light source units 110 to 110 are defined as the pair of light source units 110 and 110 each having the laser light source 111, it is possible to improve the luminance of the fluorescence on the light irradiation surface 120a of the phosphor unit 120 with a minimum configuration.

### First Embodiment-6

In the light-emitting device 100 according to the first embodiment, the pair of light source units 110 and 110 is arranged so that the light irradiation direction W along the direction of the excitation light beam L(L1) of one light source unit 110 advancing to the light irradiation surface 120a and the light irradiation direction W along the direction of the excitation light beam L(L2) of the other light source unit 110 advancing to the light irradiation surface 120a are parallel or substantially parallel.

According to such a configuration, when the pair of light source units 110 and 110 is arranged so that the light irradiation direction W of one light source unit 110 and the light irradiation direction W of the other light source unit 110 are parallel or substantially parallel, the light irradiation directions W of one light source unit 110 and the other light source unit 110 are able to be aligned in one direction or substantially one direction.

### First Embodiment-7

In the light-emitting device 100 according to the first embodiment, the pair of light source units 110 and 110 are arranged so as to be positioned on one side and the other side opposite to the one side with the phosphor unit 120 therebetween.

According to such a configuration, when the pair of light source units 110 and 110 are arranged so as to be positioned on one side and the other side opposite to the one side with the phosphor unit 120 therebetween, it is possible to simply and easily realize a configuration of the pair of light source units 110 and 110 to overlap the excitation light beams L and L each other on the light irradiation surface 120a of the phosphor unit 120 and make the longitudinal directions of the projection light beams M in the long shape parallel or substantially parallel to each other.

### First Embodiment-8

In the light-emitting device 100 according to the first embodiment, the pair of light source units 110 and 110 are arranged so as to face each other with the phosphor unit 120 therebetween.

Here, a facing direction X is a direction in which the pair of light source units 110 and 110 face each other with the phosphor unit 120 therebetween, and the facing direction X is able to be exemplified as a direction of a virtual straight line a [refer to FIG. 2(b)] that connects the center of the light output opening 111b of the laser light source 111 of one light source unit 110 and the center of the light output opening 111b of the laser light source 111 of the other light source unit 110 in the pair of light source units 110 and 110. In the present example, the facing direction X is the light irradiation direction W or substantially the light irradiation direction W.

According to such a configuration, when the pair of light source units 110 and 110 are arranged so as to face each other with the phosphor unit 120 therebetween, sizes of the shapes of the projection light beams M(M1) and M(M2) in the direction orthogonal to the facing direction X are able to be easily matched and the positions where the pair of light source units 110 and 110 are arranged are able to be aligned on the same virtual plane or substantially the same virtual plane.

### First Embodiment-9

In the light-emitting device 100 according to the first embodiment, optical axes [that is, an optical axis of the excitation light beam (L1) of the light source unit 110 on one side and an optical axis of the excitation light beam L(L2) of the light source unit 110 on the other side] of the excitation light beams L(L1) and L(L2) of the pair of light source units 110 and 110 are positioned on the same virtual plane or substantially the same virtual plane, and the same virtual plane or substantially the same virtual plane is orthogonal or substantially orthogonal to the light irradiation surface 120a of the phosphor unit 120.

According to such a configuration, when the optical axes of the excitation light beams L(L1) and L(L2) of the pair of light source units 110 and 110 are positioned on the same virtual plane or substantially the same virtual plane and the same virtual plane or substantially the same virtual plane is orthogonal or substantially orthogonal to the light irradiation surface 120a of the phosphor unit 120, sizes of the projection light beams M(M1) and M(M2) in the direction orthogonal to the light irradiation direction W are able to be minimized, and it is possible to increase illumination on the light irradiation surface 120a by radiation of the excitation light beams L(L1) and L(L2) accordingly.

### First Embodiment-10

In the light-emitting device 100 according to the first embodiment, the pair of light source units 110 and 110 is configured (specifically arranged) to be line-symmetric or substantially line-symmetric [in the present example, line-symmetric or substantially line-symmetric with respect to a virtual normal line passing through the center of the projection light beams M(M1) and M(M2) on the light irradiation surface 120a of the phosphor unit 120].

According to such a configuration, when the pair of light source units 110 and 110 is configured to be line-symmetric or substantially line-symmetric, commonality of components is able to be achieved and the pair of light source units 110 and 110 is able to be arranged with a simple configuration, thus making it possible to realize further reduction of the size of the light-emitting device 100. This is particularly effective when the pair of light source units 110 and 110 is configured to be line-symmetric or substantially line-symmetric with respect to the virtual normal line passing through the center of the projection light beams M(M1) and M(M2) on the light irradiation surface 120a of the phosphor unit 120.

Here, the center of the projection light beam M is able to be exemplified as the center of a straight line which is the longest among straight lines drawn from one end to the other end of the projection light beam M in the long shape. Note that, in a case where the projection light beams M to M have different centers, a position obtained by averaging the centers or the center of a straight line which is the longest among straight lines drawn from one end to the other end in a part where the projection light beams M to M overlap each other may be used.

### First Embodiment-11

Meanwhile, in a case where the shapes of the cross sections orthogonal to the optical axis directions of the excitation light beams L to L output from the laser light sources 111 to 111 of the light source units 110 to 110 are different from each other, and/or in a case where the incidence angles θ to θ of the excitation light beams L to L radiated to the light irradiation surface 120a of the phosphor unit 120 are different from each other, a part that protrudes from a part where the projection light beams M to M overlap each other on the light irradiation surface 120a of the phosphor unit 120 is easily formed, and the projection light beam M(M1) on the light irradiation surface 120a by the excitation light beam L(L1) projected onto the light irradiation surface 120a from one light source unit 110 of the pair of light source units 110 and 110 and the projection light beam M(M2) on the light irradiation surface 120a by the excitation light beam L(L2) projected onto the light irradiation surface 120a from the other light source unit 110 are difficult to be matched or substantially matched, for example. Thus, it is desired that the projection light beams M to M on the light irradiation surface 120a by the excitation light beams L to L projected onto the light irradiation surface 120a from the light source units 110 to 110 are easily matched or substantially matched with each other.

In this respect, in the light-emitting 100 according to the first embodiment, the shapes of the cross sections orthogonal to the optical axis directions of the excitation light beams L to L output from the laser light sources 111 to 111 of the light source units 110 to 110 are defined to be all equal or substantially equal and the light source units 110 to 110 are configured (specifically arranged, or more specifically arranged being adjusted) so that the incidence angles θ to θ of the excitation light beams L to L radiated to the light irradiation surface 120a of the phosphor unit 120 are equal or substantially equal to each other.

According to such a configuration, when the shapes of the cross sections orthogonal to the optical axis directions of the excitation light beams L to L output from the laser light sources 111 to 111 of the light source units 110 to 110 are defined to be all equal or substantially equal and the light source units 110 to 110 are configured so that the incidence angles θ to θ of the excitation light beams L to L radiated to the light irradiation surface 120a of the phosphor unit 120 are equal or substantially equal to each other, the projection light beams M to M on the light irradiation surface 120a by the excitation light beams L to L projected onto the light irradiation surface 120a from the light source units 110 to 110 are easily matched or substantially matched with each other, so that it is possible to eliminate or substantially eliminate a part that protrudes from a part where the projection light beams M to M overlap each other on the light irradiation surface 120a of the phosphor unit 120, resulting that it is possible to further improve the light intensity of the fluorescence F without waste.

### First Embodiment-12

In the light-emitting device 100 according to the first embodiment, the light source units 110 to 110 respectively include the reflection mirrors 112 to 112 that reflect the excitation light beams L to L output from the laser light sources 111 to 111. The phosphor unit 120 emits the fluorescence F by receiving the excitation light beams L to L reflected by the reflection mirrors 112 to 112 of the light source units 110 to 110.

According to such a configuration, when the light source units 110 to 110 respectively include the reflection mirrors 112 to 112 and the phosphor unit 120 emits the fluorescence F by receiving the excitation light beams L to L reflected by the reflection mirrors 112 to 112 of the light source units 110 to 110, the laser light sources 111 to 110 are able to be arranged on a side opposite to the light irradiation surface 120a of the phosphor unit 120. Accordingly, it is possible to improve a degree of freedom in design related to the arrangement of the laser light sources 111 to 111.

### First Embodiment-13

In the light-emitting device 100 according to the first embodiment, the light source units 110 to 110 are configured (specifically arranged, or more specifically arranged being adjusted) so that the excitation light beams L to L that are output by the laser light sources 111 to 111 to the reflection mirrors 112 to 112 are parallel or substantially parallel to each other.

According to such a configuration, when the light source units 110 to 110 are configured so that the excitation light beams L to L that are output by the laser light sources 111 to 111 to the reflection mirrors 112 to 112 are parallel or substantially parallel to each other, the excitation light beams L to L are able to be output by the laser light sources 111 to 111 in the same direction or substantially the same direction, thus making it possible to realize further reduction in the size of the light-emitting device 100.

### First Embodiment-14

In the light-emitting device 100 according to the first embodiment, the light source units 110 to 110 are configured (specifically arranged, or more specifically arranged being adjusted) so that all the excitation light beams L to L that are output by the laser light sources 111 to 111 to the reflection mirrors 112 to 112 are orthogonal or substantially orthogonal to the light irradiation surface 120a of the phosphor unit 120.

According to such a configuration, when the light source units 110 to 110 are configured so that all the excitation light beams L to L that are output by the laser light sources 111 to 111 to the reflection mirrors 112 to 112 are orthogonal or substantially orthogonal to the light irradiation surface 120a of the phosphor unit 120, the excitation light beams L to L are able to be output from the laser light sources 111 to 111 in a direction orthogonal or substantially orthogonal to the light irradiation surface 120a, thus making it possible to realize further reduction in the size of the light-emitting device 100.

### First Embodiment-15

In the light-emitting device 100 according to the first embodiment, a reflective light emitting principle in which the excitation light beams L to L are radiated to the light irradiation surface 120a of the phosphor unit 120 to output the fluorescence F from the light irradiation surface 120a is used.

According to such a configuration, use of the reflective light emitting principle allows suitable usage in an application of a so-called reflective light-emitting device 100.

### First Embodiment-16

As described above, the light-emitting device 100 according to the first embodiment further includes the projecting lens 170 that projects the fluorescence F from a surface (in the present example, the light irradiation surface 120a) on a side in which the fluorescence F is output among the light irradiation surface 120a and the surface 120b opposite to the light irradiation surface 120a in the phosphor unit 120.

The projecting lens 170 refracts the fluorescence F that is transmitted and thereby projects the fluorescence F in a given angle range. The projecting lens 170 is arranged on a side in which the fluorescence F is output from the light irradiation surface 120a of the phosphor unit 120. Specifically, the projecting lens 170 is provided so as to face a surface (in the present example, the light irradiation surface 120a) on a side in which the fluorescence F is output.

According to such a configuration, when the projecting lens 170 is provided, the fluorescence F from the phosphor unit 120 is able to be projected in a predefined given direction and a predefined given angle range, resulting that the fluorescence F from the phosphor unit 120 is able to be projected in a desired direction and a desired angle range.

### First Embodiment-17

In the light-emitting device 100 according to the first embodiment, the incidence angles θ to θ [in the present example, θ(θ1) and θ(θ2)] of the excitation light beams L to L [in the present example, L(L1) and L(L2)] to the light irradiation surface 120a of the phosphor unit 120 are larger than take-in angles δ to δ [in the present example, δ(δ1) and δ(δ2)] [refer to FIG. 1] of the projecting lens 170.

According to such a configuration, when the incidence angles θ to θ of the excitation light beams L to L to the light irradiation surface 120a of the phosphor unit 120 are larger than the take-in angles δ to δ of the projecting lens 170, the fluorescence F from the phosphor unit 120 is able to be taken in the projecting lens 170 without waste, and the fluorescence F from the phosphor unit 120 is able to be efficiently projected from the projecting lens 170 accordingly.

Here, the take-in angles δ to δ are angles formed by a virtual normal line passing through the center of the projection light beams M to M on the light irradiation surface 120a of the phosphor unit 120 and a virtual straight line passing through each end of the projecting lens 170 and the center of the projection light beams M to M. The center of the projection light beam M is able to be exemplified as the center of a straight line which is the longest among straight lines drawn from one end to the to the other end of the projection light beam M in the long shape.

### Second Embodiment

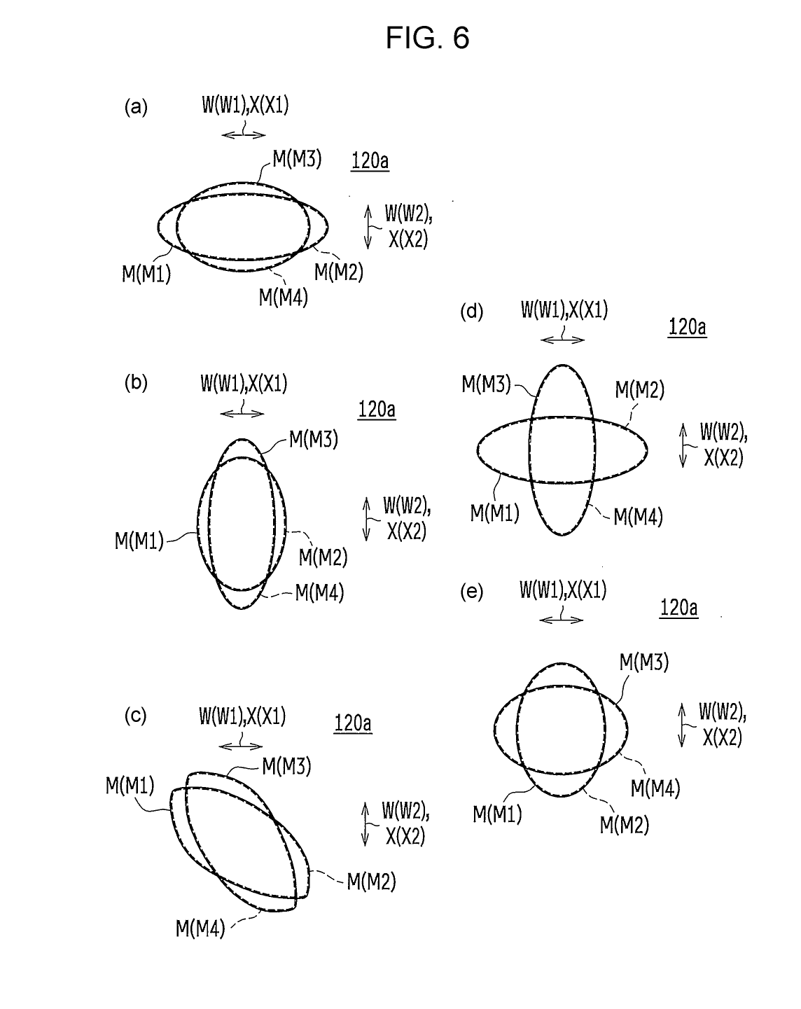

A light-emitting device 100 according to a second embodiment includes a plurality of pairs (in the present example, two pairs) of the light source units 110 and 110 (refer to FIGS. 5 and 6 described later).

According to such a configuration, when the plurality of pairs (in the present example, two pairs) of the light source units 110 and 110 are provided, it is possible to further increase the luminance of the fluorescence F on the light irradiation surface 120a of the phosphor unit 120.

### Second Embodiment-1

In the light-emitting device 100 according to the second embodiment, at least two pairs of light source units [in the present example, all the pairs of light source units (110 and 110) to (110 and 110)] of the plurality of pairs of light source units (110 and 110) to (110 and 110) are configured (specifically arranged, or more specifically arranged being adjusted) so that the excitation light beams (L and L) to (L and L) overlap each other on the light irradiation surface 120a of the phosphor unit 120.

According to such a configuration, when the plurality of pairs of light source units (110 and 110) to (110 and 110) are configured so that the excitation light beams (L and L) to (L and L) overlap each other on the light irradiation surface 120a of the phosphor unit 120, it is possible to further increase the light intensity of the fluorescence F at a part where the excitation light beams (L and L) to (L and L) overlap each other on the light irradiation surface 120a of the phosphor unit 120.

### Second Embodiment-2

In the light-emitting device 100 according to the second embodiment, the plurality of pairs of light source units (110 and 110) to (110 and 110) are configured (specifically arranged) so that the light source units of each of at least two pairs of light source units [in the present example, all the pairs of light source units (110 and 110) to (110 and 110)] are line-symmetric or substantially line-symmetric [in the present example, line-symmetric or substantially line-symmetric with respect to a virtual normal line passing through the center of the projection light beams M to M on the light irradiation surface 120a of the phosphor unit 120].

According to such a configuration, in a case where the plurality of pairs of light source units (110 and 110) to (110 and 110) are configured so that the light source units of each of at least two pairs of light source units are line-symmetric or substantially line-symmetric, even when a plurality of pairs of light source units 110 and 110 are provided, commonality of components is able to be achieved and the plurality of pairs of light source units (110 and 110) to (110 and 110) are able to be arranged with a simple configuration, thus making it possible to realize further reduction in the size of the light-emitting device 100. This is particularly effective when the light source units of each of the plurality of pairs of light source units (110 and 110) to (110 and 110) are configured to be line-symmetric or substantially line-symmetric with respect to the virtual normal line passing through the center of the projection light beams M to M on the light irradiation surface 120a of the phosphor unit 120.

Note that, the center of the projection light beam M is similar to that described in the first embodiment-10, and is therefore not described repeatedly.

### Second Embodiment-3

In the light-emitting device 100 according to the second embodiment, the plurality of pairs of light source units (110 and 110) to (110 and 110) are arranged so that the light source units of each of at least two pairs of light source units [in the present example, all the pairs of light source units (110 and 110) to (110 and 110)] face each other with the phosphor unit 120 therebetween.

According to such a configuration, when the plurality of pairs of light source units (110 and 110) to (110 and 110) are arranged so that the light source units of each of at least two pairs of light source units face each other with the phosphor unit 120 therebetween, sizes of the shapes of the projection light beams M and M in the direction orthogonal to the facing direction X are able to be easily matched in each of the pairs of light source units 110 and 110 and the positions where the respective pairs of light source units 110 and 110 are arranged are able to be aligned on the same virtual plane or substantially the same virtual plane.

### Second Embodiment-4

FIG. 5 is a schematic view illustrating an example of the light-emitting device 100 according to the second embodiment, in which FIGS. 5(a) and 5(b) are respectively a side view and a plan view illustrating an example that the light-emitting device 100 according to the first embodiment further includes a pair of light source units 110 and 110.

In the light-emitting device 100 illustrated in FIG. 5, members that have substantially the same configuration as that of the light-emitting device 100 according to the first embodiment are given the same reference signs and description thereof is omitted.

In an example of the light-emitting device 100 according to the second embodiment, a plurality of pairs (in the present example, two pairs) of light source units (110 and 110) to (110 and 110) are configured (specifically arranged) so that, in a pair of light source units (110 and 110) and another pair of light source units (110 and 110) of the plurality of pairs of light source units (110 and 110) to (110 and 110), a first facing direction X(X1) in which the light source units (110 and 110) as the pair face each other and a second facing direction X(X2) in which the light source units (110 and 110) as the other pair face each other are orthogonal or substantially orthogonal.

The pair of light source units (110 and 110) has a similar configuration to that of the light-emitting device 100 according to the first embodiment, and is therefore not described repeatedly.

The other pair of light source units (110 and 110) is configured (specifically arranged, or more specifically arranged being adjusted) so that excitation light beams L(L3) and (L4) overlap each other on the light irradiation surface 120a of the phosphor unit 120 (preferably, so that at least one of the excitation light beams entirely overlaps other excitation light beams on the light irradiation surface 120a) when the light irradiation surface 120a is irradiated with the excitation light beams L(L3) and (L4), and so that longitudinal directions of projection light beams M(M3) and M(M4) in the long shape on the light irradiation surface 120a by the excitation light beams L(L3) and (L4) projected onto the light irradiation surface 120a are parallel or substantially parallel to each other. Other configurations are also similar to the configurations of the light-emitting device 100 according to the first embodiment, and are therefore not described repeatedly here.

The first facing direction X(X1) is a first light irradiation direction W(W1) or substantially first light irradiation direction W(W1) along directions of the excitation light beams L(L1) and L(L2) advancing to the light irradiation surface 120a and the second facing direction X(X2) is a second light irradiation direction W(W2) or substantially second light irradiation direction W(W2) along directions of the excitation light beams L(L3) and L(L4) advancing to the light irradiation surface 120a.

According to such a configuration, in a case where a pair of light source units (110 and 110) and another pair of light source units (110 and 110) of the plurality of pairs (in the present example, two pairs) of light source units (110 and 110) to (110 and 110) are configured so that the first facing direction X(X1) in which the light source units (110 and 110) as the pair face each other and the second facing direction X(X2) in which the light source units (110 and 110) as the other pair face each other are orthogonal or substantially orthogonal, even when a plurality of pairs of light source units 110 and 110 are provided, the plurality of pairs of light source units (110 and 110) to (110 and 110) are able to be provided radially (for example, so that distances between optical axes of adjacent light source units 110 and 110 are equal) around the light irradiation surface 120a of the phosphor unit 120, specifically, a predefined given point (for example, center point) of the light irradiation surface 120a, thus making it possible to realize downsizing of the light-emitting device 100.

### About Example of Projection Light Beams of Second Embodiment-4

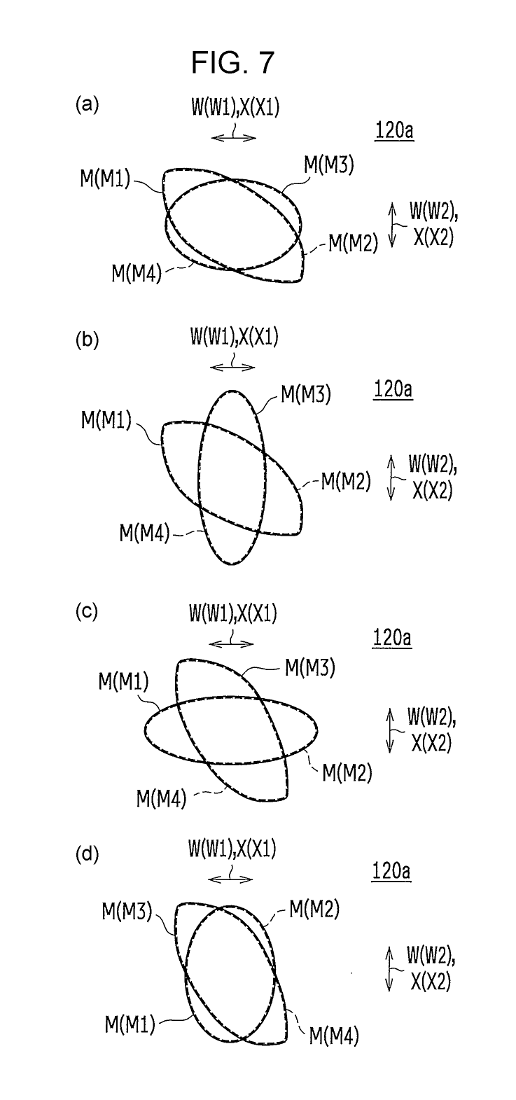

FIGS. 6 and 7 are schematic plan views illustrating projection light beams [M(M1) and M(M2)] and [M(M3) and M(M4)] on the light irradiation surface 120a by the excitation light beams [L(L1) and L(L2)] and [L(L3) and L(L4)] projected onto the light irradiation surface 120a in the example of the light-emitting device 100 according to the second embodiment illustrated in FIG. 5. FIGS. 6(a) to 6(e) and FIGS. 7(a) to 7(d) illustrate each example thereof.

In the example illustrated in FIG. 6(a), longitudinal directions of shapes of the projection light beams M(M1) and M(M2) by the excitation light beams [L(L1) and L(L2)] from a pair of light source units (110 and 110) are parallel or substantially parallel to the first light irradiation direction W(W1) [first facing direction X(X1)] and longitudinal directions of shapes of the projection light beams M(M3) and M(M4) by the excitation light beams [L(L3) and L(L4)] from another pair of light source units (110 and 110) are orthogonal or substantially orthogonal to the second light irradiation direction W(W2) [second facing direction X(X2)].

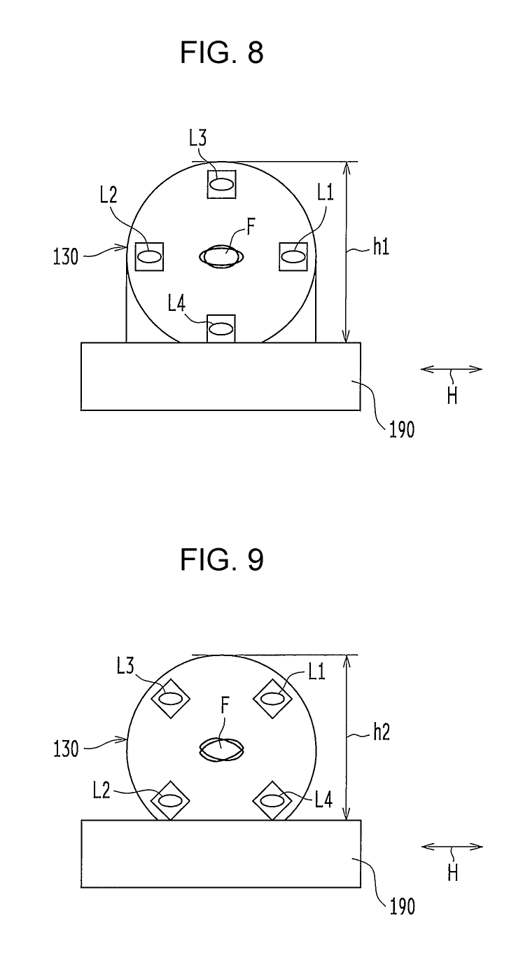

FIG. 8 is a schematic sectional view illustrating a case where the main body chassis 130 is fixed to a table 190 in the example illustrated in FIG. 6(a). In FIG. 8, components other than the excitation light beams L1 to L4, the fluorescence F, the main body chassis 130, and the table 190 are not illustrated so as to describe a relationship between sectional shapes of the excitation light beams L1 to L4 and a sectional shape of the fluorescence F. According to such a configuration, a longitudinal direction of the fluorescence F is horizontal or substantially horizontal, thus allowing suitable usage in an application, such as a head lamp for a vehicle, in which directivity characteristics that are wide in a horizontal direction H are desired.

In the example illustrated in FIG. 6(b), the longitudinal directions of the shapes of the projection light beams M(M1) and M(M2) by the excitation light beams [L(L1) and L(L2)] from a pair of light source units (110 and 110) are orthogonal or substantially orthogonal to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are parallel or substantially parallel to the second light irradiation direction W(W2) [second facing direction X(X2)].

In the example illustrated in FIG. 6(c), the longitudinal directions of the shapes of the projection light beams M(M1) and M(M2) by the excitation light beams [L(L1) and L(L2)] from a pair of light source units (110 and 110) are oblique in relation to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are oblique in relation to the second light irradiation direction W(W2) [second facing direction X(X2)].

FIG. 9 is a schematic sectional view illustrating a case where the main body chassis 130 is fixed to the table 190 in the example illustrated in FIG. 6(c). In FIG. 9, components other than the excitation light beams L1 to L4, the fluorescence F, the main body chassis 130, and the table 190 are not illustrated so as to describe a relationship between the sectional shapes of the excitation light beams L1 to L4 and the sectional shape of the fluorescence F. According to such a configuration, the longitudinal direction of the fluorescence F is horizontal or substantially horizontal, thus allowing suitable usage in an application, such as a head lamp for a motor vehicle, in which directivity characteristics that are wide in the horizontal direction H are desired. Further, in comparison to the examples illustrated in FIGS. 8 and 6(a), two adjacent excitation light beams (the excitation light beams L2 and L4 or the excitation light beams L1 and L3 in the example illustrated in FIG. 9) are arranged in the horizontal direction or substantially horizontal direction, so that a circular arc portion (a lower part in the example illustrated in FIG. 9), on the table 190 side, of the main body chassis 130 in a cylindrical shape is able to be omitted. That is, a height h1 (refer to FIG. 8) of the main body chassis 130 is able to be further reduced (refer to a height h2 of the main body chassis 130 illustrated in FIG. 9), thus allowing suitable usage for a head lamp for a motor vehicle or the like from a viewpoint of downsizing of a device and reduction in air resistance during moving.

In the example illustrated in FIG. 6(d), the longitudinal directions of the shapes of the projection light beams M(M1) and M(M2) by the excitation light beams [L(L1) and L(L2)] from a pair of light source units (110 and 110) are parallel or substantially parallel to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are parallel or substantially parallel to the second light irradiation direction W(W2) [second facing direction X(X2)].

In the example illustrated in FIG. 6(e), the longitudinal directions of the shapes of the projection light beams M(M1) and M(M2) by the excitation light beams [L(L1) and L(L2)] from a pair of light source units (110 and 110) are orthogonal or substantially orthogonal to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are orthogonal or substantially orthogonal to the second light irradiation direction W(W2) [second facing direction X(X2)].

In the example illustrated in FIG. 7(a), the longitudinal directions of the shapes of the projection light beams M(M1) and M(M2) by the excitation light beams [L(L1) and L(L2)] from a pair of light source units (110 and 110) are oblique in relation to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are orthogonal or substantially orthogonal to the second light irradiation direction W(W2) [second facing direction X(X2)].

In the example illustrated in FIG. 7(b), the longitudinal directions of the shapes of the projection light beams M(M1) and M(M2) by the excitation light beams [L(L1) and L(L2)] from a pair of light source units (110 and 110) are oblique in relation to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are parallel or substantially parallel to the second light irradiation direction W(W2) [second facing direction X(X2)].

In the example illustrated in FIG. 7(c), the longitudinal directions of the shapes of the projection light beams M(M1) and M(M2) by the excitation light beams [L(L1) and L(L2)] from a pair of light source units (110 and 110) are parallel or substantially parallel to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are oblique in relation to the second light irradiation direction W(W2) [second facing direction X(X2)].

In the example illustrated in FIG. 7(d), the longitudinal directions of the shapes of the projection light beams M(M1) and M(M2) by the excitation light beams [L(L1) and L(L2)] from a pair of light source units (110 and 110) are orthogonal or substantially orthogonal to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are oblique in relation to the second light irradiation direction W(W2) [second facing direction X(X2)].

According to the configurations illustrated in FIGS. 6(a) to 6(c), longitudinal sizes of the projection light beams M(M1), M(M2), M(M3), and M(M4) are large, thus allowing suitable usage in an application (for example, a head lamp for a vehicle which is desired to have directivity characteristics that are wide in a horizontal direction) in which directivity characteristics that are wide in a given straight line direction are desired.

According to the configurations illustrated in FIGS. 6(d), 6(e), and 7(a) to 7(d), the shapes of the projection light beams M(M1), M(M2), M(M3), and M(M4) approach a perfect circle, thus allowing suitable usage in an application (for example, a flood lamp which is desired to have directivity characteristics that are wide in substantially all directions) in which directivity characteristics that are wide in substantially all directions are desired.

Note that, though an example that the light-emitting device 100 includes two pairs of light source units 110 and 110 is indicated in the example of the configuration of the second embodiment-4, a plurality of sets may be provided with two pairs of light source units (110 and 110) and light source units (110 and 110) as one set.

### Second Embodiment-5

FIG. 10 is a schematic view illustrating another example of the light-emitting device 100 according to the second embodiment, in which FIGS. 10(a) and 10(b) are respectively a side view and a plan view illustrating another example that the light-emitting device 100 according to the first embodiment further includes a pair of light source units 110 and 110.

In the light-emitting device 100 illustrated in FIG. 10, members that have substantially the same configuration as that of the light-emitting device 100 according to the first embodiment are given the same reference signs and description thereof is omitted.

In another example of the light-emitting device 100 according to the second embodiment, a plurality of pairs (in the present example, two pairs) of light source units (110 and 110) to (110 and 110) are configured (specifically arranged) so that, in a pair of light source units (110 and 110) and another pair of light source units (110 and 110) of the plurality of pairs of light source units (110 and 110) to (110 and 110), the first facing direction X(X1) in which the light source units (110 and 110) as the pair face each other and the second facing direction X(X2) in which the light source units (110 and 110) as the other pair face each other are parallel or substantially parallel.

The pair of light source units (110 and 110) has a similar configuration to that of the light-emitting device 100 according to the first embodiment, and is therefore not described repeatedly. The other pair of light source units (110 and 110) has a similar configuration to that of the light-emitting device 100 according to the second embodiment-4 illustrated in FIG. 5, and is therefore not described repeatedly.

The first facing direction X(X1) is a first light irradiation direction W(W1) or substantially first light irradiation direction W(W1) along directions of the excitation light beams L(L1) and L(L2) advancing to the light irradiation surface 120a and the second facing direction X(X2) is a second light irradiation direction W(W2) or substantially second light irradiation direction W(W2) along directions of the excitation light beams L(L3) and L(L4) advancing to the light irradiation surface 120a.

According to such a configuration, in a case where a pair of light source units (110 and 110) and another pair of light source units (110 and 110) of the plurality of pairs (in the present example, two pairs) of light source units (110 and 110) to (110 and 110) are configured so that the first facing direction X(X1) in which the light source units (110 and 110) as the pair face each other and the second facing direction X(X2) in which the light source units (110 and 110) as the other pair face each other are parallel or substantially parallel, even when a plurality of pairs of light source units 110 and 110 are provided, the plurality of pairs of light source units (110 and 110) to (110 and 110) are able to be provided along one direction [first and second facing directions X(X1) and X(X2)], thus making it possible to achieve downsizing in a direction orthogonal to the one direction.

In the present example, the optical axes of the excitation light beams L [L(L1) and L(L2)] of the pair of light source units (110 and 110) and optical axes of the excitation light beams L [L(L3) and L(L4)] of the other pair of light source units (110 and 110) are on the same virtual plane or substantially the same virtual plane, and the same virtual plane or substantially the same virtual plane is orthogonal or substantially orthogonal to the light irradiation surface 120a of the phosphor unit 120. As a result, the plurality of pairs of light source units (110 and 110) to (110 and 110) are able to be provided on a straight line along one direction [first and second facing directions X(X1) and X(X2)], thus making it possible to realize further downsizing in a direction orthogonal to the one direction.

Moreover, in the present example, the light source units 110 to 110 are arranged so that incidence angles θ to θ (θ1, θ2, θ3, and θ4) [refer to FIG. 10(a)] of excitation light beams radiated to the light irradiation surface 120a increase as approaching an outer side from an inner side with the phosphor unit 120 therebetween, specifically, with a predefined given point (for example, center point) of the light irradiation surface 120a therebetween. As a result, the light source units 110 to 110 are able to be efficiently arranged. Noe that, when distances between the light source units 110 and the phosphor unit 120 are equal or substantially equal, the incidence angles θ are able to be defined to be the same or substantially the same.

### About Example of Projection Light Beams of Second Embodiment-5

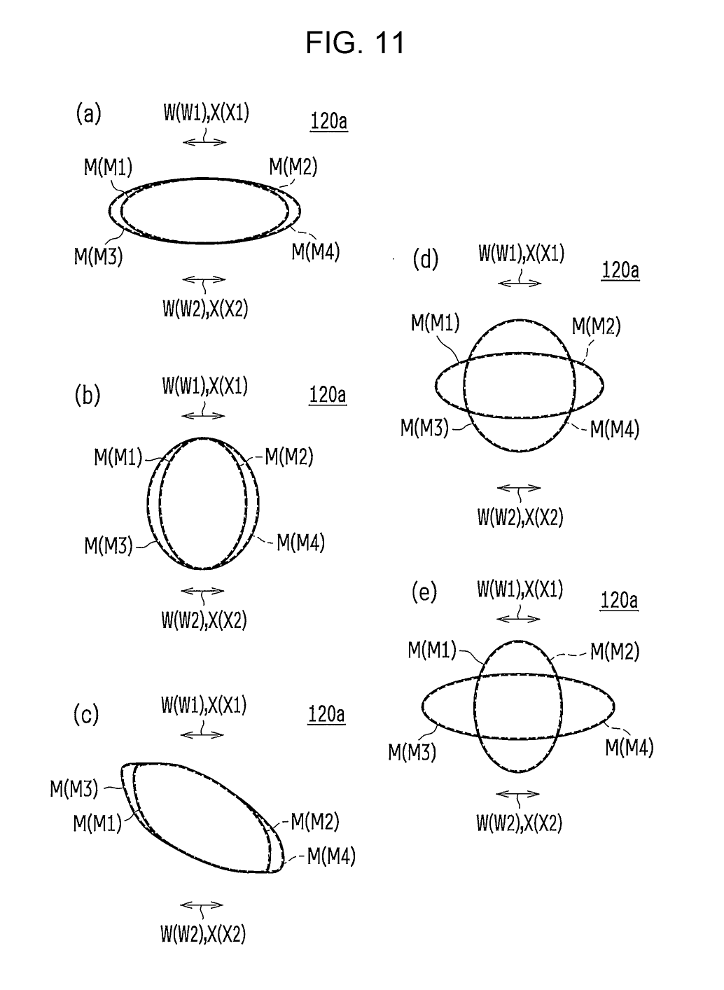

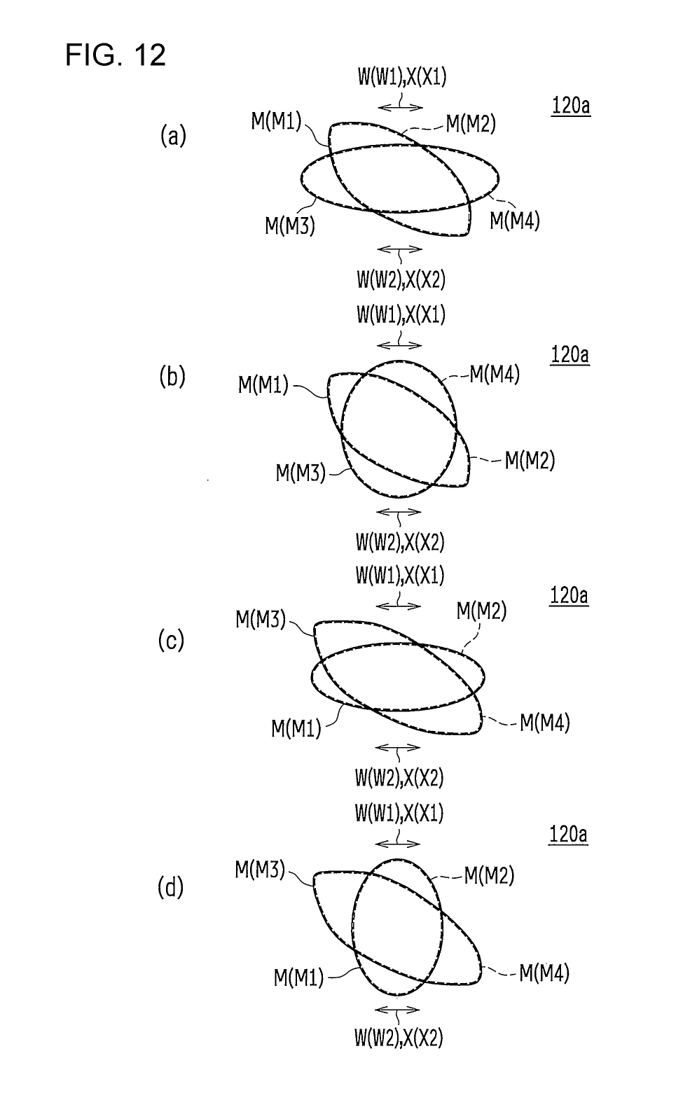

FIGS. 11 and 12 are schematic plan views illustrating the projection light beams [M(M1) and M(M2)], [M(M3) and M(M4)] on the light irradiation surface 120a by the excitation light beams [L(L1) and L(L2)], [L(L3) and L(L4)] projected onto the light irradiation surface 120a in another example of the light-emitting device 100 according to the second embodiment illustrated in FIG. 10. FIGS. 11(a) to 11(e) and FIGS. 12(a) to 12(d) illustrate each example thereof.

Here, longitudinal lengths of the projection light beams [M(M3) and M(M4)] are longer than longitudinal lengths of the projection light beams [M(M1) and M(M2)]. This is because the incidence angles θ3 and θ4 are larger than the incidence angles θ1 and θ2 and the projection light beams [M(M3) and M(M4)] are larger than the projection light beams [M(M1) and M(M2)] in dL/cos θ.

In the example illustrated in FIG. 11(a), the longitudinal directions of the shapes of the projection light beams M(M1) and M(M2) by the excitation light beams [L(L1) and L(L2)] from a pair of light source units (110 and 110) are parallel or substantially parallel to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are parallel or substantially parallel to the second light irradiation direction W(W2) [second facing direction X(X2)].

In the example illustrated in FIG. 11(b), the longitudinal directions of the shapes of the projection light beams M(M1) and M(M2) by the excitation light beams [L(L1) and L(L2)] from a pair of light source units (110 and 110) are orthogonal or substantially orthogonal to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are orthogonal or substantially orthogonal to the second light irradiation direction W(W2) [second facing direction X(X2)].

In the example illustrated in FIG. 11(c), the longitudinal directions of the shapes of the projection light beams M(M1) and M(M2) by the excitation light beams [L(L1) and L(L2)] from a pair of light source units (110 and 110) are oblique in relation to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are oblique in relation to the second light irradiation direction W(W2) [second facing direction X(X2)].

In the example illustrated in FIG. 11(d), the longitudinal directions of the shapes of the projection light beams M(M1) and M(M2) by the excitation light beams [L(L1) and L(L2)] from a pair of light source units (110 and 110) are parallel or substantially parallel to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are orthogonal or substantially orthogonal to the second light irradiation direction W(W2) [second facing direction X(X2)].

In the example illustrated in FIG. 11(e), the longitudinal directions of the shapes of the projection light beams M(M1) and M(M2) by the excitation light beams [L(L1) and L(L2)] from a pair of light source units (110 and 110) are orthogonal or substantially orthogonal to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are parallel or substantially parallel to the second light irradiation direction W(W2) [second facing direction X(X2)].

In the example illustrated in FIG. 12(a), the longitudinal directions of the shapes of the projection light beams M(M1) and M(M2) by the excitation light beams [L(L1) and L(L2)] from a pair of light source units (110 and 110) are oblique in relation to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are parallel or substantially parallel to the second light irradiation direction W(W2) [second facing direction X(X2)].

In the example illustrated in FIG. 12(b), the longitudinal directions of the shapes of the projection light beams M(M1) and M(M2) by the excitation light beams [L(L1) and L(L2)] from a pair of light source units (110 and 110) are oblique in relation to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are orthogonal or substantially orthogonal to the second light irradiation direction W(W2) [second facing direction X(X2)].

In the example illustrated in FIG. 12(c), the longitudinal directions of the shapes of the projection light beams M(M1) and M(M2) by the excitation light beams [L(L1) and L(L2)] from a pair of light source units (110 and 110) are parallel or substantially parallel to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are oblique in relation to the second light irradiation direction W(W2) [second facing direction X(X2)].

In the example illustrated in FIG. 12(d), the longitudinal directions of the shapes of the projection light beams M(M1) and M(M2) by the excitation light beams [L(L1) and L(L2)] from a pair of light source units (110 and 110) are orthogonal or substantially orthogonal to the first light irradiation direction W(W1) [first facing direction X(X1)] and the longitudinal directions of the shapes of the projection light beams M(M3) and M(M4) by the excitation light beams [L(L3) and L(L4)] from another pair of light source units (110 and 110) are oblique in relation to the second light irradiation direction W(W2) [second facing direction X(X2)].

According to the configurations illustrated in FIGS. 11(a) to 11(c), longitudinal sizes of the shapes of the projection light beams M(M1), M(M2), M(M3), and M(M4) are large, thus allowing suitable usage in an application (for example, a head lamp for a vehicle which is desired to have directivity characteristics that are wide in a horizontal direction) in which directivity characteristics that are wide in a given straight line direction are desired.

According to the configurations illustrated in FIGS. 11(d), 11(e), and 12(a) to 12(d), the shapes of the projection light beams M(M1), M(M2), M(M3), and M(M4) approach a perfect circle, thus allowing suitable usage in an application (for example, a flood lamp which is desired to have directivity characteristics that are wide in substantially all directions) in which directivity characteristics that are wide in substantially all directions are desired.

Note that, in the example of the configuration of the second embodiment-5, the plurality of pairs of light source units may be configured to further include, in addition to a pair of light source units (110 and 110) and another pair of light source units (110 and 110), a still another pair of light source units (110 and 110) and a still different pair of light source units (110 and 110), which are not illustrated, and configured so that, in the still another pair of light source units (110 and 110) and the still different pair of light source units (110 and 110), a third facing direction in which the light source units (110 and 110) as the still another pair face each other and a fourth facing direction in which the light source units (110 and 110) as the still different pair face each other are parallel or substantially parallel and the third and fourth facing directions are orthogonal or substantially orthogonal to the first and second facing directions X(X1) and X(X2).

Moreover, though an example that two pairs of light source units 110 and 110 are provided in the light-emitting device 100 is indicated in the example of the configuration the second embodiment-5, three or more pairs may be provided.

Moreover, in the example of the configuration of the second embodiment-5, though the light source units 110 to 110 are arranged so that the incidence angles of the excitation light beams radiated to the light irradiation surface 120a increase as approaching an outer side from an inner side with the phosphor unit 120 therebetween, a similar configuration may be applied also to another configuration in which a plurality of light source units 110 are provided.

In the present embodiment, though a configuration in which the incidence angles of the excitation light beams radiated to the phosphor unit 120 in one direction (in the present example, a right-and-left direction) are equal is provided, that is, it is set as follows: (incidence angle θ1 of excitation light beam L1=incidence angle θ2 of excitation light beam L2) and (incidence angle θ3 of excitation light beam L3=incidence angle θ4 of excitation light beam L4), the excitation light beams L might not be symmetric. For example, it is also possible that the excitation light beam L2 and the excitation light beam L4 are omitted and the excitation light beam L1 and the excitation light beam L3 are used in combination. In such a configuration, though an overlapping effect of the spots is reduced compared to a case where the incidence angles are equal, a given overlapping effect of the spots is able to be expected by aligning the longitudinal directions of the spots, and the configuration is particularly effective, for example, when there is a restriction on an installation place of the light source units 110.

### Third Embodiment

FIG. 13 is a schematic view illustrating a light-emitting device 100 according to a third embodiment and is a sectional view illustrating an example that the light irradiation surface 120a of the phosphor unit 120 is directly irradiated with the excitation light beams L to L from the light source units 110 to 110.

The light-emitting device 100 according to the third embodiment illustrated in FIG. 13 has a similar configuration to that of the light-emitting device 100 according to the first embodiment, except that the mirror units 160 to 160 are removed from the light-emitting device 100 according to the first embodiment and the light irradiation surface 120a of the phosphor unit 120 is directly irradiated with the excitation light beams L to L from the light source units 110 to 110.

In the light-emitting device 100 illustrated in FIG. 13, members that have substantially the same configuration as that of the light-emitting device 100 according to the first embodiment are given the same reference signs and description thereof is omitted.

The light-emitting device 100 illustrated in FIG. 13 is configured so that the light irradiation surface 120a of the phosphor unit 120 is directly irradiated with the excitation light beams L to L from the light source units 110 to 110.

In the present example, the laser light sources 111 to 111 are provided at positions between the phosphor unit 120 and the projecting lens 170.

In the light-emitting device 100 illustrated in FIG. 13, the light irradiation surface 120a of the phosphor unit 120 is irradiated with the excitation light beams L to L output from the laser light sources 111 to 111, so that the fluorescence F is generated. Then, the fluorescence F output from the surface (in the present example, the light irradiation surface 120a) on the side in which the fluorescence F is output is projected to the outside through the projecting lens 170.

According to such a configuration, the configuration in which the light irradiation surface 120a of the phosphor unit 120 is directly irradiated with the excitation light beams L to L from the laser light sources 110 to 110 enables a simple configuration of the light-emitting device 100, and it is possible to reduce the size of the light-emitting device 100 accordingly.

Note that, in the example of the configuration of the third embodiment, though the mirror units 160 to 160 are removed from the light-emitting device 100 according to the first embodiment so that the light irradiation surface 120a of the phosphor unit 120 is directly irradiated with the excitation light beams L to L from the light source units 110 to 110, the mirror units 160 to 160 may be removed from the light-emitting device 100 according to the second embodiment, or a fifth embodiment or a sixth embodiment that is described below so that the light irradiation surface 120a of the phosphor unit 120 is directly irradiated with the excitation light beams L to L from the light source units 110 to 110.

### Fourth Embodiment

FIG. 14 is a schematic view illustrating a light-emitting device 100 according to a fourth embodiment and is a sectional view illustrating an example of a transmissive configuration.

The light-emitting device 100 according to the fourth embodiment has a transmissive configuration instead of the reflective configuration of the light-emitting device 100 according to the third embodiment.

In the light-emitting device 100 illustrated in FIG. 14, members that have substantially the same configuration as that of the light-emitting device 100 according to the first embodiment are given the same reference signs and description thereof is omitted.

In the light-emitting device 100 according to the fourth embodiment, a transmissive light emitting principle in which the excitation light beams L to L are radiated to the light irradiation surface 120a of the phosphor unit 120 to output the fluorescence F from the surface 120b opposite to the light irradiation surface 120a is used.

According to such a configuration, use of the transmissive light emitting principle enables suitable usage in an application of a so-called transmissive light-emitting device 100.

Note that, in the example of the configuration of the fourth embodiment, though the transmissive configuration is used instead of the reflective configuration of the light-emitting device 100 according to the third embodiment, the transmissive configuration may be used instead of a reflective configuration of the light-emitting device 100 according to the first embodiment or the second embodiment, or the fifth embodiment or the sixth embodiment that is described below.

### Fifth Embodiment

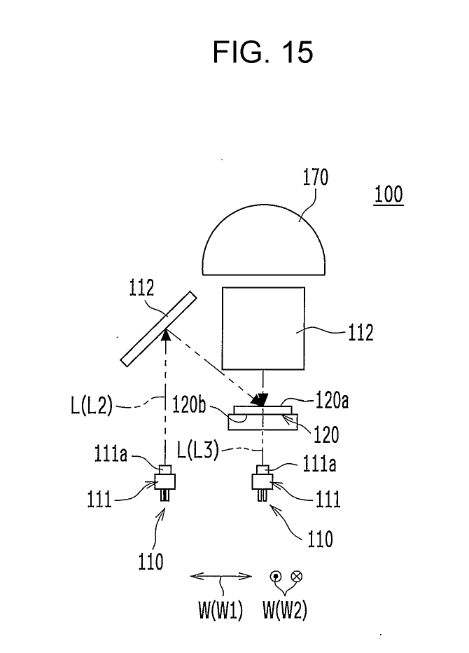

FIG. 15 is a schematic view illustrating a light-emitting device 100 according to the fifth embodiment and is a side view illustrating an example that light irradiation directions W and W of a pair of light source units 110 and 110 cross each other.

The light-emitting device 100 illustrated in FIG. 15 is obtained by removing any one light source unit 110 of a pair of light source units (110 and 110) and any one light source unit 110 of another pair of light source units (110 and 110) from the configuration of the second embodiment-4 (an example of the light-emitting device 100 according to the second embodiment) illustrated in FIG. 5.

In the light-emitting device 100 illustrated in FIG. 15, members that have substantially the same configuration as that of the light-emitting device 100 according to the second embodiment-4 are given the same reference signs and description thereof is omitted.

In the light-emitting device 100 illustrated in FIG. 15, a pair of light source units 110 and 110 is arranged so that the light irradiation direction W(W1) along the direction of the excitation light beam L(L3) of one light source unit 110 advancing to the light irradiation surface 120a cross (in the present example, is orthogonal or substantially orthogonal to) the light irradiation direction W(W2) along the direction of the excitation light beam L(L2) of the other light source unit 110 advancing to the light irradiation surface 120a.

According to such a configuration, when the pair of light source units 110 and 110 is arranged so that the light irradiation direction W along the direction of the excitation light beam L of one light source unit 110 advancing to the light irradiation surface 120a cross the light irradiation direction W along the direction of the excitation light beam L of the other light source unit 110 advancing to the light irradiation surface 120a, no light source units 110 and 110 are provided on a side opposite to the light source units 110 and 110 with the phosphor unit 120 therebetween, thus making it possible to effectively use a space on the opposite side.

Note that, three or more light source units 110 to 110 may be provided. In this case, the three or more light source units 110 to 110 are able to be provided radially (for example, so that distances between optical axes of adjacent light source units 110 and 110 are equal) around the light irradiation surface 120a of the phosphor unit 120, specifically, a predefined given point (for example, center point) of the light irradiation surface 120a.

### Sixth Embodiment

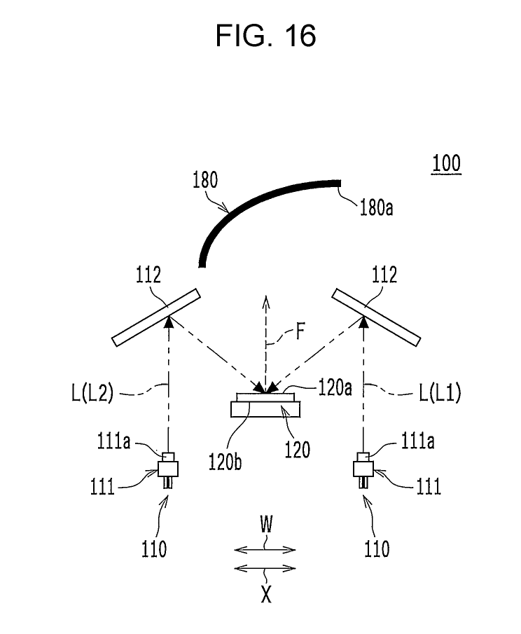

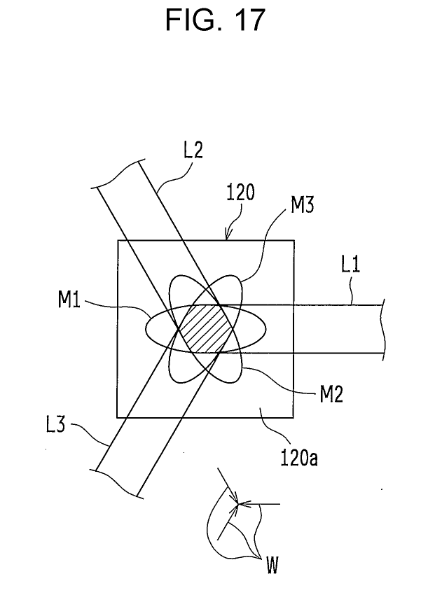

FIG. 16 is a schematic view illustrating a light-emitting device 100 according to the sixth embodiment and is a side view illustrating an example that a reflector 180 is provided.

The light-emitting device 100 illustrated in FIG. 16 is obtained by providing the reflector 180 instead of or in addition to (in the present example, instead of) the projecting lens 170 in the configuration of the first embodiment illustrated in FIG. 2.

In the light-emitting device 100 illustrated in FIG. 16, members that have substantially the same configuration as that of the light-emitting device 100 according to the first embodiment are given the same reference signs and description thereof is omitted.

The light-emitting device 100 illustrated in FIG. 16 includes the reflector 180 that projects the fluorescence F from the light irradiation surface 120a of the phosphor unit 120.

According to such a configuration, when the reflector 180 that projects the fluorescence F from the light irradiation surface 120a of the phosphor unit 120 is provided, even a simple configuration makes it possible to project the fluorescence F from the phosphor unit 120 in a predefined given direction, thus making it possible to project the fluorescence F from the phosphor unit 120 in a desired direction.

The light-emitting device 100 illustrated in FIG. 16 is able to be suitably used for a head lamp (head lamp for a vehicle) of a motor vehicle, for example.

The reflector 180 projects the fluorescence F output from the light irradiation surface 120a of the phosphor unit 120. The reflector 180 may be, for example, a member in which a metal thin film is formed on an inner surface of a resin member or may be a metal member.

The reflector 180 includes a reflecting curved surface that is formed by causing a parabola to rotate with a symmetry axis of the parabola serving as the rotation axis, and at least a part of a partially curved surface obtained by cutting the reflecting curved surface on a plane parallel to the rotation axis is included in the reflecting curved surface. The reflector 180 has an opening 180a in a semicircular shape in a direction in which the fluorescence F output from the light irradiation surface 120a of the phosphor unit 120 is projected. The light irradiation surface 120a of the phosphor unit 120 is arranged at approximately a focal point position of the reflector 180.

In the light-emitting device 100 having such a configuration, the fluorescence F generated on the light-irradiation surface 120a of the phosphor unit 120 is projected from the opening 180a of the reflector 180 toward a direction of a vehicle advancing while a bundle of light rays which are substantially parallel is being formed by the reflector 180. This makes it possible to efficiently project the fluorescence F, which is generated on the light irradiation surface 120a, within a narrow solid angle.

Note that, the reflector 180 may include a full parabolic mirror having the opening 180a in a circular shape or may include a part thereof. In addition to the parabolic mirror, it is possible to use a member that has an elliptical or free-curved surface shape or a multifaceted member (multi-reflector). Furthermore, a portion that is not a curved surface may be included in a part of the reflector 180. Alternatively, the reflector 180 may be configured to project the fluorescence F from the light irradiation surface 120a of the phosphor unit 120 at an enlarged scale.

Though not illustrated, an optical member, such as a projecting lens, that controls an angle range to project light may be further provided in the opening 180a of the reflector 180 in the light-emitting device 100.

In the example of the configuration of the sixth embodiment, though the reflector 180 is provided in the light-emitting device 100 according to the first embodiment, the reflector 180 may be provided in the light-emitting device 100 according to any of the second to fifth embodiments instead of or in addition to the projecting lens 170.

### OTHER EMBODIMENTS

The light-emitting device 100 according to the embodiments descried above may be applied to a head lamp for a vehicle other than a motor vehicle. Furthermore, the light-emitting device 100 is able to be applied to, but not limited to, for example, a flood lamp, a head lamp for a moving object (specifically, a moving body such as a human, a ship, an airplane, a submarine, or a rocket) other than a vehicle, a searchlight, a projector, or a lighting device such as indoor lighting equipment such as a downlight or a stand light.

The invention is not limited to the embodiments described above and can be carried out in other various forms. The embodiments are therefore to be taken in all respects as exemplary only, and are not to be interpreted as being limiting. The scope of the invention is represented by the claims and is not restricted in any way to the specification itself. Furthermore, all variations and modifications falling within the scope of the claims also fall within the scope of the invention.

This application claims priority based on Japanese Patent Application No. 2015-218509 filed in Japan on Nov. 6, 2015, the content of which is incorporated herein in its entirety.

### INDUSTRIAL APPLICABILITY

The invention relates to a light-emitting device capable of emitting fluorescence by irradiating a light irradiation surface of a phosphor unit with an excitation light beam, and is applicable to intended use to improve luminance of the fluorescence on the light irradiation surface, particularly when the light irradiation surface of the phosphor unit is irradiated with a plurality of excitation light beams in an overlapping manner.

### REFERENCE SIGNS LIST

100 light-emitting device
110 light source unit
111 laser light source
111a semiconductor laser element
111b light output opening
112 reflection mirror
120 phosphor unit
120a light irradiation surface
120b surface opposite to light irradiation surface
130 main body chassis
131 housing unit
132 excitation-light-passing hole
133 projection-light-passing hole
140 light source unit
141 collimate lens
142 screw structure
150 pressing plate
160 mirror unit
161 holding member
170 projecting lens
180 reflector
180a opening
F fluorescence
Kmax longest straight line
L excitation light beam
M projection light beam
SC fixing member
W light irradiation direction
X facing direction
α virtual straight line
δ take-in angle
δ incidence angle
φ angle

1. A light-emitting device comprising:
a plurality of light source units each having a laser light source that outputs excitation light; and
a phosphor unit that receives the excitation light and emits fluorescence, wherein
at least two light source units of the plurality of light source units are configured so that excitation light beams overlap each other on a light irradiation surface of the phosphor unit when the light irradiation surface is irradiated with the excitation light beams and so that longitudinal directions of projection light beams in long shapes on the light irradiation surface by the excitation light beams projected onto the light irradiation surface are parallel or substantially parallel to each other.

2. The light-emitting device according to claim 1, wherein
the plurality of light source units are configured so that the longitudinal directions of the shapes of all the projection light beams are parallel or substantially parallel to each other.

3. The light-emitting device according to claim 2, wherein
the longitudinal directions of the shapes of the projection light beams are horizontal directions or substantially horizontal directions when the fluorescence is projected to an outside.

4. The light-emitting device according to claim 1, wherein
the longitudinal directions of the shapes of the projection light beams of the at least two light source units are parallel or substantially parallel to a light irradiation direction along directions of the excitation light beams advancing to the light irradiation surface.

5. The light-emitting device according to claim 1, wherein
the longitudinal directions of the shapes of the projection light beams of the at least two light source units are orthogonal or substantially orthogonal to a light irradiation direction along directions of the excitation light beams advancing to the light irradiation surface.
